(19) United States
(12) Patent Application Publication
(10) Pub. No.: US 2025/0344459 A1
(43) Pub. Date: Nov. 6, 2025

(54) SEMICONDUCTOR DEVICE AND METHODS OF FORMATION

(71) Applicant: Taiwan Semiconductor Manufacturing Company, Ltd., Hsinchu (TW)

(72) Inventors: Yi-Hong WANG, Taichung City (TW); Yi-Chen LI, Taichung City (TW)

(21) Appl. No.: 18/638,132

(22) Filed: Apr. 17, 2024

(51) Int. Cl. H10D 48/00; H10D 48/01; H10D 48/36

(52) U.S. Cl. CPC H10D 48/383; H10D 48/032; H10D 48/362

(57) ABSTRACT

A fin-based tunneling filed field effect transistor (TFET) includes a control gate structure and an assisting gate structure adjacent to the control gate structure. The assisting gate structure is disposed between the control gate structure and a source/drain region of the fin-based TFET. When a voltage is applied to the assisting gate structure, the assisting gate structure causes the valence band of the fin-based TFET to be raised near the junction between the source/drain region and a channel region in a semiconductor layer under the assisting gate structure. This reduces the tunneling distance between the source/drain region and the channel region, which allows for a lesser threshold voltage to be used for the control gate structure than without the assisting gate structure.

### BACKGROUND

Fin-based transistors, such as fin field effect transistors (finFETs) and nanostructure transistors (e.g., nanowire transistors, nanosheet transistors, gate-all-around (GAA) transistors, multi-bridge channel transistors, nanoribbon transistors), are three-dimensional structures that include a channel region in a fin (or a portion thereof) that extends above a semiconductor substrate as a three-dimensional structure. A gate structure, configured to control a flow of charge carriers within the channel region, wraps around the fin of semiconductor material. As an example, in a finFET, the gate structure wraps around three sides of the fin (and thus the channel region), thereby enabling increased control over the channel region (and therefore switching of the finFET). A source region and a drain region (e.g., epitaxial regions) are located on opposing sides of the gate structure and/or the channel region.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 and 2A-2I are diagrams of examples of a semiconductor device described herein.

FIGS. 3A-3G are diagrams of examples of band diagrams for one or more of the fin-based tunneling field effect transistor (TFET) structures described herein.

FIGS. 4A-4D are diagrams of an example of forming fin structures in a semiconductor device described herein.

FIGS. 5A and 5B are diagrams of an example of forming a doped semiconductor capping layer in a semiconductor device described herein.

FIGS. 6A-6C are diagrams of an example of forming a doped semiconductor capping layer in a semiconductor device described herein.

FIGS. 7A-7H are diagrams of an example of forming a fin-based TFET structure of the semiconductor device.

FIG. 8 is a diagram of an example of a semiconductor device described herein.

FIG. 9 is a diagram of an example of a semiconductor device described herein.

FIG. 10 is a diagram of examples of dielectric materials that may be used in a gate dielectric layer stack of a fin-based TFET structure described herein.

FIG. 11 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a fin-based transistor may be switched between off and on states through thermionic emission, such as in the case of a fin-based metal-oxide semiconductor field effect transistor (MOSFET). Another type of fin-based transistor is a fin-based tunneling field effect transistor (TFET). Unlike a fin-based MOSFET, switching of a fin-based TFET is implemented through quantum tunneling. A gate voltage may be applied to a gate of a fin-based TFET to modify a valence band (Eᵥ) of the fin-based TFET. In particular, the valence band is raised to the level of a conduction band (E_{c}) of the fin-based TFET, which enables charge carriers to tunnel directly between the valence band and the conduction band. This enables an electrical current to flow between source/drain regions of the fin-based TFET through quantum tunneling.

Some implementations described herein include a fin-based TFET that includes a control gate structure and an assisting gate structure adjacent to the control gate structure. The assisting gate structure is disposed between the control gate structure and a source/drain region of the fin-based TFET. “Source/drain region” may refer to a source region, a drain region, or a source and drain region, depending on the context. When a voltage is applied to the assisting gate structure, the assisting gate structure causes the valence band of the fin-based TFET to be raised near the junction between the source/drain region and a channel region in a semiconductor layer under the assisting gate structure. This reduces the tunneling distance between the source/drain region and the channel region, which allows for a lesser threshold voltage to be used for the control gate structure than without the assisting gate structure. In this way, the assisting gate structure may increase switching speed and power efficiency of the fin-based TFET (e.g., because of the lesser threshold voltage).

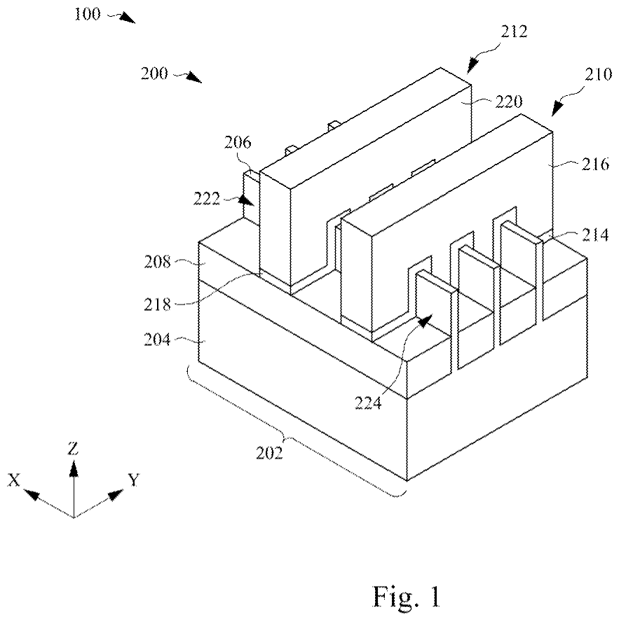

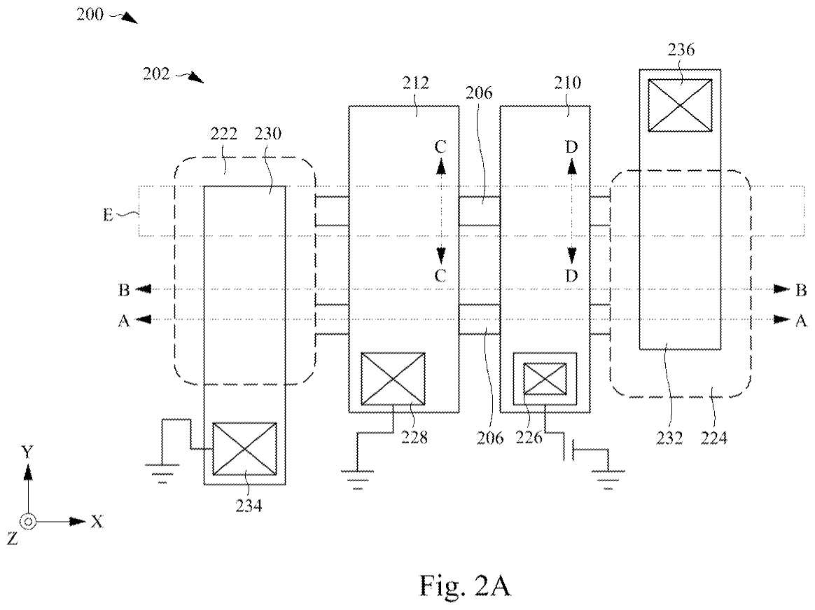

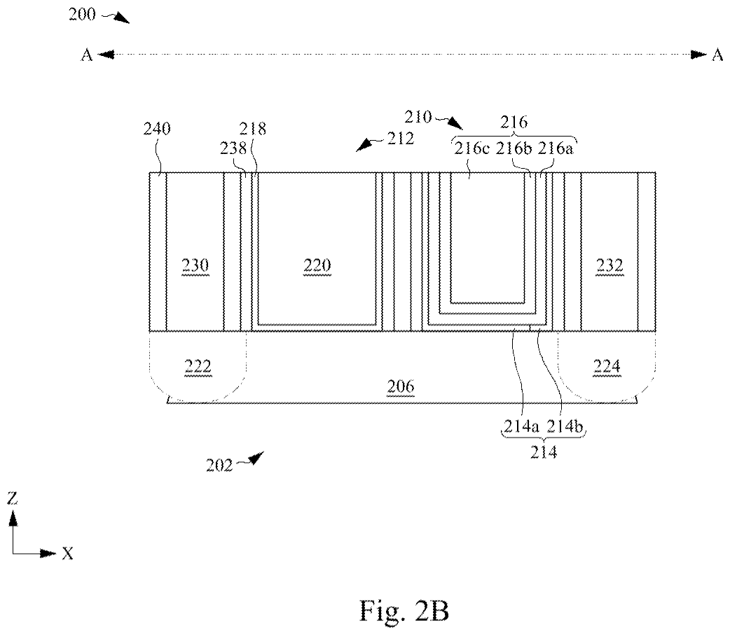

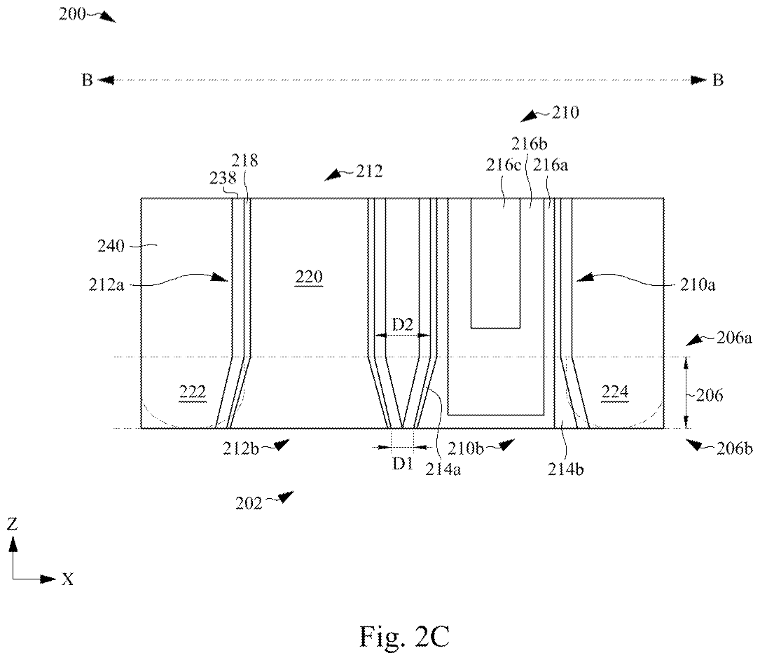

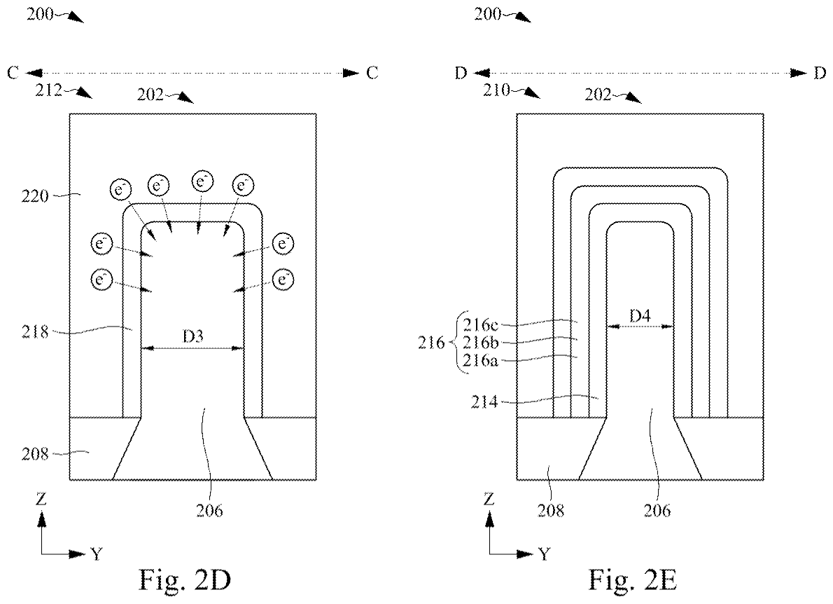

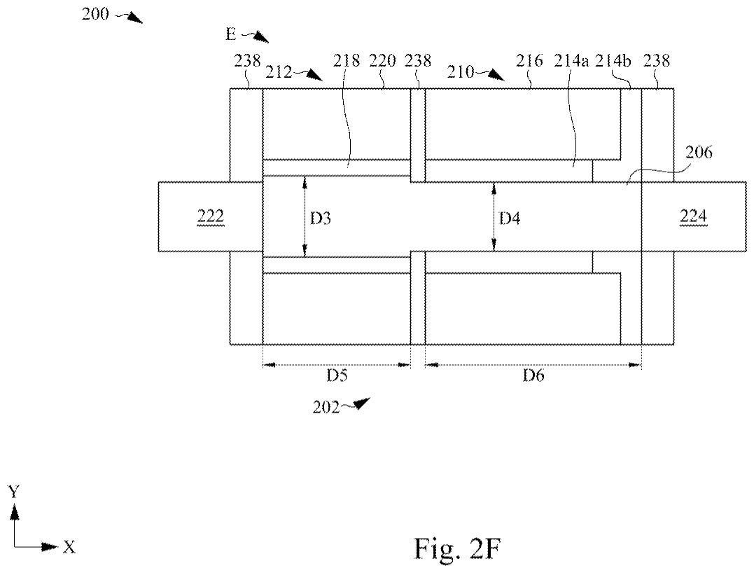

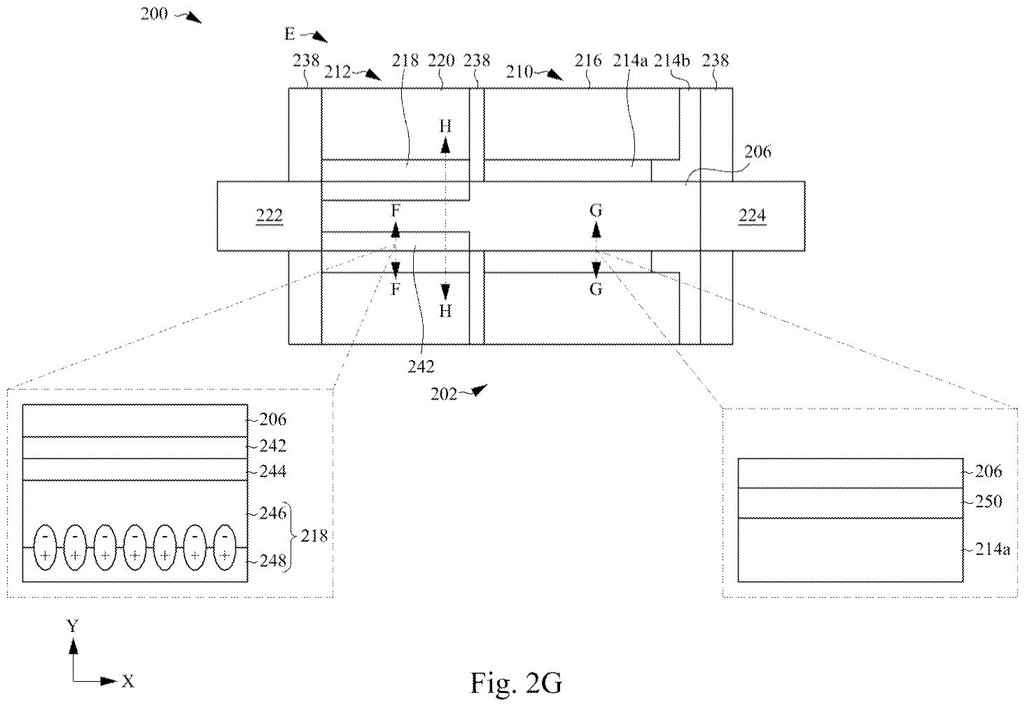

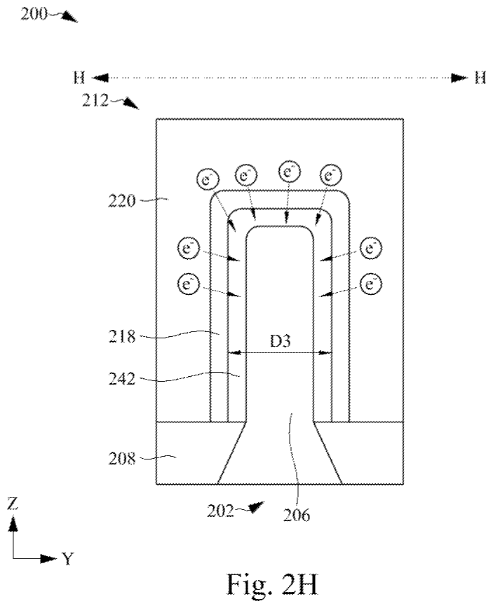

FIGS. 1 and 2A-2I are diagrams of examples of a semiconductor device 200 described herein. FIGS. 1 and 2A-2I illustrates examples of a fin-based TFET structure 202 of the semiconductor device 200. In some implementations, the fin-based TFET structure 202 includes a p-type fin-based TFET structure 202, an n-type fin-based TFET structure 202, and/or another type of fin-based TFET structure 202. In some implementations, the semiconductor device 200 includes a plurality of fin-based TFET structures 202. The fin-based TFET structure 202 may be formed according to one or more of the examples illustrated in FIGS. 1 and 2A-2I, and/or may be arranged in a complementary metal oxide semiconductor (CMOS) integrated circuit in the semiconductor device 200, and/or another examples.

FIG. 1 is an example 100 of a perspective view of the fin-based TFET structure 202 of the semiconductor device 200. As shown in FIG. 1, fin-based TFET structure 202 is formed above a substrate 204 of the semiconductor device 200. The substrate 204 includes a silicon (Si) substrate, a substrate formed of a material including silicon, a III-V compound semiconductor material substrate such as gallium arsenide (GaAs), a silicon on insulator (SOI) substrate, a germanium substrate (Ge), a silicon germanium (SiGe) substrate, or another type of semiconductor substrate. The substrate 204 may include a round/circular substrate having an approximately 200 mm diameter, an approximately 300 mm diameter, or another diameter, such as 450 mm, among other examples. The substrate 204 may alternatively be any polygonal, square, rectangular, curved, or otherwise non-circular workpiece, such as a polygonal substrate.

Fin structures 206 are included above (and/or extend above) the substrate 204 in a z-direction in the semiconductor device 200. The fin structures 206 extend in an x-direction in the semiconductor device 200 and are arranged in a y-direction in the semiconductor device 200. The fin-based TFET structure 202 may include one or more of the fin structures 206. A fin structure 206 may provide an active region where one or more devices (e.g., fin-based transistors) are formed. In some implementations, the fin structures 206 include silicon (Si) materials or another elementary semiconductor material such as germanium (Ge). In some implementations, the fin structures 206 include an alloy semiconductor material such as silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), gallium indium arsenide phosphide (GaInAsP), or a combination thereof. A portion of a fin structure 206 may function as a channel region of a fin-based TFET structure 202. The channel region may include an undoped portion of the fin structure 206.

The fin structures 206 are fabricated by suitable semiconductor process techniques, such as masking, photolithography, and/or etch processes, among other examples. As an example, the fin structures 206 may be formed by etching a portion of the substrate 204 away to form recesses in the substrate 204. The recesses may then be filled with isolating material that is recessed or etched back to form shallow trench isolation (STI) regions 208 above the substrate 204 and between the fin structures 206. Other fabrication techniques for the STI regions 208 and/or for the fin structures 206 may be used. The STI regions 208 may electrically isolate adjacent active areas in the fin structures 206. The STI regions 208 may include a dielectric material such as a silicon oxide (SiOₓ), a silicon nitride (SiₓN_{y}), a silicon oxynitride (SiON), fluoride-doped silicate glass (FSG), a low-k dielectric material, and/or other suitable insulating material. The STI regions 208 may include a multi-layer structure, for example, having one or more liner layers.

A control gate structure 210 of the fin-based TFET structure 202 is included over the fin structures 206. The control gate structure 210 extends in the y-direction such that the control gate structure 210 is approximately perpendicular to the fin structures 206. The control gate structure 210 engages the fin structures 206 on three or more sides of the fin structures 206. “Control gate structure” refers to the main gate structure of the fin-based TFET structure 202. The control gate structure 210 is responsible for switching the fin-based TFET structure 202 between an on state and an off state. A control gate voltage may be selectively applied to the control gate structure 210 to switch the fin-based TFET structure 202 between the on state and the off state. For example, the fin-based TFET structure 202 may be switched to the on state by applying the control gate voltage to the control gate structure 210, and may be switched to the off state by removing the control gate voltage from the control gate structure 210.

An assisting gate structure 212 of the fin-based TFET structure 202 is included over the fin structures 206, and extends in the y-direction such that the assisting gate structure 212 is approximately perpendicular to the fin structures 206. The assisting gate structure 212 is adjacent to the control gate structure 210 and extends approximately parallel to the control gate structure 210. “Assisting gate structure” refers to an auxiliary gate structure of the fin-based TFET structure 202. The assisting gate structure 212 may be used to modify the valence band of the fin-based TFET structure 202 (e.g., by applying an assisting gate voltage to the assisting gate structure 212) such that lesser threshold voltages can be used for the control gate structure 210 to switch the fin-based TFET structure 202 between the on state and the off state. The assisting gate structure 212 engages the fin structures 206 on three or more sides of the fin structures 206.

The control gate structure 210 includes a gate dielectric layer 214 and a gate electrode 216. The gate dielectric layer 214 may include one or more low dielectric constant (low-k) dielectric layers and/or one or more high dielectric constant (high-k) dielectric layers, among other examples. “Low-k dielectric material” may refer to a dielectric material having a dielectric constant that is less than or approximately equal to the dielectric constant of silicon dioxide (SiO₂—approximately 3.9). Examples include fluoride-doped silicate glass (FSG), undoped silicate glass (USG), a boron-containing silicate glass (BSG), carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples. “High-k dielectric material” may refer to a dielectric material having a dielectric constant that is greater than the dielectric constant of silicon dioxide. Examples include aluminum oxide (AlₓO_{y} such as Al₂O₃), zirconium oxide (ZrOₓ), hafnium oxide (HfOₓ), lanthanum oxide (La₂O₃), silicon nitride (SiₓN_{y}), and/or yttrium oxide (YₓO_{y} such as Y₂O₃), among other examples.

The gate electrode 216 includes one or more metal materials. Examples, include tungsten (W), aluminum (Al), cobalt (Co), ruthenium (Ru), and/or titanium (Ti), among other examples. In some implementations, the gate electrode 216 includes one or more work metals layers for tuning the work function of the control gate structure 210. Examples of work function metals include selenium (Se), platinum (Pt), iridium (Ir), nickel (Ni), gold (Au), cobalt (Co), rubidium (Rb), terbium (Tb), strontium (Sr), neodymium (Nd), yttrium (Y), aluminum (Al), and/or titanium (Ti), among other examples.

The assisting gate structure 212 includes a gate dielectric layer 218 and a gate electrode 220. The gate dielectric layer 218 may include one or more low-k dielectric layers and/or one or more high-k dielectric layers, among other examples. In some implementations, the gate dielectric layer 218 includes one or more materials that are different from the material(s) of the gate dielectric layer 214. In some implementations, the gate dielectric layer 218 includes one or more materials that are also included in the gate dielectric layer 214.

The gate electrode 220 includes one or more metal materials. In some implementations, the gate electrode 220 includes one or more work function metals layer for tuning the work function of the assisting gate structure 212. In some implementations, the gate electrode 220 includes one or more materials that are also included in the gate electrode 216. In some implementations, the gate electrode 220 includes one or more materials that are different from the material(s) of the gate electrode 216. For example, the gate electrode 220 may include different work function metal(s) than the work function metals(s) of the gate electrode layer 216. This enables work function metal(s) to be selected for the gate electrode 216 to optimize the switching speed of the control gate structure 210, and enables work function metal(s) to be selected for the gate electrode 220 to optimize the band bending of the valence band and/or the conduction band of the fin-based TFET structure 202.

Source/drain regions 222 and 224 are disposed on the fin structures 206. The source/drain regions 222 are located adjacent to a first side of the assisting gate structure 212, and the source/drain regions are located adjacent to a first side of the control gate structure 210. The second sides of the assisting gate structure 212 and the control gate structure 210 are facing each other. Thus, the control gate structure 210 is capable of controlling quantum tunneling of charge carriers through the fin structures 206 (e.g., through the channel regions in the fin structures 206) between the source/drain regions 222 and the source/drain regions 224, and the assisting gate is capable of enhancing the quantum tunneling of charge carriers from the source/drain regions 222 in the channel regions of the fin structures 206.

The source/drain regions 222 and 224 include regions of semiconductor material (e.g., silicon (Si)) that are doped with one or more dopants. For example, the source/drain regions 222 may include silicon that is doped with one or more p-type dopants (e.g., boron (B) or germanium (Ge), among other examples) and the source/drain regions 224 may include silicon that is doped with one or more n-type dopants (e.g., phosphorous (P) or arsenic (As), among other examples) in implementations in which a fin-based TFET structure 202 is an n-type TFET (NTFET). For an NTFET, the assisting gate voltage that is applied to the assisting gate structure 212 may be less than or approximately equal to 0 volts.

As another example, the source/drain regions 222 may include silicon that is doped with one or more n-type dopants and the source/drain regions 224 may include silicon that is doped with one or more p-type dopants in implementations in which a fin-based TFET structure 202 is a p-type TFET (PTFET). For a PTFET, the assisting gate voltage that is applied to the assisting gate structure 212 may be greater than or approximately equal to 0 volts.

FIG. 2A is a top-down view of an example of a fin-based TFET structure 202. As shown in FIG. 2A, the control gate structure 210 is electrically coupled and/or physically coupled with a gate contact 226. The control gate voltage may be applied to the control gate structure 210 through the gate contact 226. Similarly, the assisting gate structure 212 is electrically coupled and/or physically coupled with a gate contact 228. The assisting gate voltage may be applied to the assisting gate structure 212 through the gate contact 228. The source/drain region 222 is electrically coupled and/or physically coupled with a source/drain contact 230, and the source/drain region 224 is electrically coupled and/or physically coupled with a source/drain contact 232. The source/drain contact 230 is electrically coupled and/or physically coupled with a source/drain interconnect 234, and the source/drain contact 232 is electrically coupled and/or physically coupled with a source/drain interconnect 236. The gate contacts 226 and 228, and the source/drain interconnects 234 and 236, may each extend in the z-direction in the semiconductor device 200. The source/drain contacts 230 and 232 may each extend in the y-direction and/or in the x-direction in the semiconductor device 200. The gate contacts 226 and 228, the source/drain contacts 230 and 232, and the source/drain interconnects 234 and 236 may each include conductive plugs, vias, trenches, conductive columns, and/or another type of conductive structure. The gate contacts 226 and 228, the source/drain contacts 230 and 232, and the source/drain interconnects 234 and 236 may each include one or more electrically conductive materials, such as copper (Cu), tungsten (W), cobalt (Co), ruthenium (Ru), titanium (Ti), aluminum (Al), gold (Au), and/or a combination thereof, among other examples of electrically conductive materials.

FIG. 2B is a cross-section view of an example of a fin-based TFET structure 202 in the x-z plane in the semiconductor device 200. The cross-section view in FIG. 2B is in a cross-sectional plane along the line A-A in FIG. 2A (e.g., on a fin structure 206). As shown in FIG. 2B, the source/drain regions 222 and 224 may be at least partially recessed in the fin structure 206. In some implementations, the top surface of the source/drain region 222 and/or the top surface of the source/drain region 224 extends above the top surface of the fin structure 206. The channel region of the fin-based TFET structure 202 corresponds to the portion of the fin structure 206 between the source/drain regions 222 and 224, and under the control gate structure 210 and the assisting gate structure 212. The channel region may include an undoped intrinsic semiconductor material such as silicon (Si), among other examples.

Gate spacers 238 may be included on the sidewalls of the control gate structure 210 and/or may be included on the sidewalls of the assisting gate structure 212. The gate spacers 238 may include one or more dielectric materials, such as silicon oxide (SiOₓ), silicon nitride (SiₓN_{y}), silicon carbide (SiC), silicon oxynitride (SiON), silicon oxycarbide (SiOC), and/or silicon oxycarbonitride (SiOCN), among other examples.

The control gate structure 210, the assisting gate structure 212, and the source/drain contacts 230 and 232 may each be included in a dielectric layer 240 that is above the fin structure 206. The dielectric layer 240 may be referred to as an interlayer dielectric (ILD) layer and/or another type of dielectric layer. The dielectric layer 240 may include one or more dielectric materials, such as silicon oxide (SiOₓ), silicon nitride (SiₓN_{y}), fluoride-doped silicate glass (FSG), undoped silicate glass (USG), boron-containing silicate glass (BSG), and/or another dielectric material.

As further shown in FIG. 2B, the gate dielectric layer 214 of the control gate structure 210 may include a plurality of portions, such as a high-k portion 214a that includes one or more high-k dielectric materials, and a low-k portion 214b that includes one or more low-k dielectric materials. In some implementations, the high-k portion 214a includes one or more low-k dielectric materials in addition to the high-k dielectric material(s). The high-k portion 214a is included on a portion of a bottom surface of the gate electrode 216 of the control gate structure 210. The high-k portion 214a is also included on a sidewall of the gate electrode 216 of the control gate structure 210 (e.g., the sidewall facing the assisting gate structure 212 and opposing the sidewall of the gate electrode 216 that is facing the source/drain region 224). The low-k portion 214b is included on another portion of the bottom surface of the gate electrode 216 of the control gate structure 210. The low-k portion 214b is also included on the sidewall of the gate electrode 216 of the control gate structure 210 that is facing the source/drain region 224 and that is opposing the sidewall of the gate electrode 216 that is facing the assisting gate structure 212.

The gate electrode 216 of the control gate structure 210 may include a plurality of gate electrode layers, such as gate electrode layers 216a-216c, among other examples. The gate electrode layers 216a-216c may include different combinations of materials (e.g., different metals). For example, the gate electrode layer 216a may include titanium nitride (TiN), the gate electrode layer 216b may include titanium aluminum (TiAl) or tantalum nitride (TaN), and the gate electrode layer 216c may include tungsten (W).

The gate dielectric layer 218 of the assisting gate structure 212 be included on a portion of a bottom surface and on the sidewalls of the gate electrode 220 of the assisting gate structure 212. The gate electrode 220 of the assisting gate structure 212 may include one or more metals for tuning the work function of the assisting gate structure 212 to bring the valence band and the conduction band near each other at the junction between the source/drain region 222 and the fin structure 206. The metal(s) (e.g., the work function metal(s)) of the assisting gate structure 212 may be different from the metal(s) (e.g., the work function metal(s)) of the control gate structure 210. If the fin-based TFET structure 202 is an NTFET (e.g., the source/drain region 222 is doped with one or more p-type dopants and the source/drain region 224 is doped with one or more n-type dopants), the gate electrode 220 may include one or more metals having a work function that is greater than or approximately equal to 5.0. Examples of such metals include selenium (Se), platinum (Pt), iridium (Ir), nickel (Ni), gold (Au), and/or cobalt (Co), among other examples. If the fin-based TFET structure 202 is a PTFET (e.g., the source/drain region 222 is doped with one or more n-type dopants and the source/drain region 224 is doped with one or more p-type dopants), the gate electrode 220 may include one or more metals having a work function that is less than or approximately equal to 4.1. Examples of such metals include rubidium (Rb), terbium (Tb), strontium (Sr), neodymium (Nd), yttrium (Y), aluminum (Al), and/or titanium (Ti), among other examples.

FIG. 2C is a cross-section view of an example of a fin-based TFET structure 202 in the x-z plane in the semiconductor device 200. The cross-section view in FIG. 2C is in a cross-sectional plane along the line B-B in FIG. 2A (e.g., along a side of a fin structure 206). As shown in FIG. 2C, the cross-sectional profile of the control gate structure 210 and the cross-section profile of the assisting gate structure 212 are different along the side of the fin structure 206 than on top of the fin structure 206. Along the side of the fin structure 206, the control gate structure 210 has a top section 210a above a top surface 206a of the fin structure 206, and a bottom section 210b between the top surface 206a and a bottom surface 206b of the fin structure 206. The bottom surface 206b of a fin structure 206 corresponds to the top surface of the substrate 204. In other words, bottom surface 206b of a fin structure 206 corresponds to the interface or transition between the fin structure 206 and the substrate 204.

The top section 210a has approximately straight sidewalls that are approximately parallel with the z-direction in the semiconductor device 200, and therefore can be referred to as a straight section of the control gate structure 210. The bottom section 210b is flared and has angled sidewalls, and therefore can be referred to as a flared section of the control gate structure 210. Thus, the bottom section 210b has a cross-sectional width (referred to as the gate length of the control gate structure 210, which corresponds to a dimension D6 illustrated in FIG. 2F) that increases from the top surface 206a of the fin structure 206 to the bottom surface 206b of the fin structure 206. A transition between the flared section (e.g., the bottom section 210b) and the straight section (e.g., the top section 210a) is located approximately at a top of the first source/drain region 222 and the second source/drain region 224.

Along the side of the fin structure 206, the assisting gate structure 212 has a top section 212a above the top surface 206a of the fin structure 206, and a bottom section 212b between the top surface 206a and the bottom surface 206b of the fin structure 206. The top section 212a has approximately straight sidewalls that are approximately parallel with the z-direction in the semiconductor device 200, and therefore can be referred to as a straight section of the assisting gate structure 212. The bottom section 212b is flared and has angled sidewalls, and therefore can be referred to as a flared section of the assisting gate structure 212. Thus, the bottom section 212b has a cross-sectional width (referred to as the gate length of the assisting gate structure 212, which corresponds to a dimension D5 illustrated in FIG. 2F) that increases from the top surface 206a of the fin structure 206 to the bottom surface 206b of the fin structure 206. A transition between the flared section (e.g., the bottom section 212b) and the straight section (e.g., the top section 212a) is located approximately at a top of the first source/drain region 222 and the second source/drain region 224.

A spacing between the bottom section 210b of the control gate structure 210 and the bottom section 212b of the assisting gate structure 212 (indicated in FIG. 2C as dimension D1) is less than a spacing between the top section 210a of the control gate structure 210 and the top section 212a of the assisting gate structure 212 (indicated in FIG. 2C as dimension D2) due to the flared cross-sectional profiles of the bottom section 210b of the control gate structure 210 and the bottom section 212b of the assisting gate structure 212.

In some implementations, the dimension D1 is greater than approximately 0 nanometers and less than or equal to approximately 6 nanometers. If the dimension D1 is 0 nanometers, the control gate structure 210 and the assisting gate structure 212 would be in physical contact, resulting in direct tunneling between the control gate structure 210 and the assisting gate structure 212 and high current leakage. If the dimension D1 is greater than approximately 6 nanometers, the tunneling width for the fin-based TFET structure 202 may be too large, resulting in ineffective shortening of the tunneling distance between the valence band and the conduction band of the fin-based TFET structure 202. If the dimension D1 is greater than approximately 0 nanometers and less than or equal to approximately 6 nanometers, a sufficiently low current leakage and short tunneling distance may be achieved for the fin-based TFET structure 202. However, other values for the dimension D1, and ranges other than greater than approximately 0 nanometers and less than or equal to approximately 6 nanometers, are within the scope of the present disclosure.

In some implementations, the dimension D2 is included in a range of approximately 1.1 times the gate length of the control gate structure 210 to approximately 2.5 times the gate length of the control gate structure 210. If the dimension D2 is less than approximately 1.1 times the gate length of the control gate structure 210, the control gate structure 210 and the assisting gate structure 212 would be in physical contact, resulting in direct tunneling between the control gate structure 210 and the assisting gate structure 212 and high current leakage. If the dimension D2 is greater than approximately 2.5 times the gate length of the control gate structure 210, the tunneling width for the fin-based TFET structure 202 may be too large, resulting in ineffective shortening of the tunneling distance between the valence band and the conduction band of the fin-based TFET structure 202. If the dimension D2 is included in the range of approximately 1.1 times the gate length of the control gate structure 210 to approximately 2.5 times the gate length of the control gate structure 210, a sufficiently low current leakage and short tunneling distance may be achieved for the fin-based TFET structure 202. However, other values for the dimension D2, and ranges other than approximately 1.1 times the gate length of the control gate structure 210 to approximately 2.5 times the gate length of the control gate structure 210, are within the scope of the present disclosure.

FIGS. 2D and 2E illustrate cross-sectional views of an example of a fin-based TFET structure 202 in the y-z plane in the semiconductor device 200. The cross-section view in FIG. 2D is in a cross-sectional plane along the line C-C in FIG. 2A (e.g., across a fin structure 206 and along an assisting gate structure 212). The cross-section view in FIG. 2E is in a cross-sectional plane along the line D-D in FIG. 2A (e.g., across a fin structure 206 and along a control gate structure 210).

As shown in FIG. 2D, the assisting gate structure 212 wraps around the fin structure 206 on at least three sides of the fin structure 206. As shown in FIG. 2E, the control gate structure 210 wraps around the fin structure 206 on at least three sides of the fin structure 206. A cross-sectional width in the y-direction of the fin structure 206 under the assisting gate structure 212 corresponds to dimension D3 in FIG. 2D. A cross-sectional width in the y-direction of the fin structure 206 under the control gate structure 210 corresponds to dimension D4 in FIG. 2D. In some implementations, the cross-sectional width of the fin structure 206 under the assisting gate structure 212 (e.g., the dimension D3) is greater than the cross-sectional width of the fin structure 206 under the control gate structure 210 (e.g., the dimension D4). The greater cross-sectional width of the fin structure 206 under the assisting gate structure 212 promotes vertical tunneling into the fin structure 206 (e.g., tunneling of charge carries into the fin structure 206 through the top of the fin structure 206) under the assisting gate structure 212. In some implementations, the cross-sectional width of the fin structure 206 under the assisting gate structure 212 (e.g., the dimension D3) and the cross-sectional width of the fin structure 206 under the control gate structure 210 (e.g., the dimension D4) are approximately equal.

FIG. 2F is a cross-sectional view of an example of a fin-based TFET structure 202 in a cross-sectional plane E in FIG. 2A, which is in the x-y plane in the semiconductor device 200. The cross-sectional plane E is located at a bottom of the fin structure 206 illustrated in FIG. 2F. FIG. 2F illustrates the dimension D3 (e.g., the width of the fin structure 206 under the assisting gate structure 212) and the dimension D4 (e.g., the width of the fin structure 206 under the control gate structure 210) in the cross-sectional plane E.

FIG. 2F further illustrates the dimension D5 (e.g., the gate length of the assisting gate structure 212) and the dimension D6 (e.g., the gate length of the control gate structure 210) in the cross-sectional plane E. As indicated above, the dimension D1 (e.g., the spacing between the top section 210a of the control gate structure 210 and the top section 212a of the assisting gate structure 212) may be included in a range of approximately 1.1 times the dimension D6 to approximately 2.5 times the dimension D6. However, other values for the range are within the scope of the present disclosure. In some implementations, the dimension D5 (e.g., the gate length of the assisting gate structure 212) is less than the dimension D6 (e.g., the gate length of the control gate structure 210). In some implementations, the dimension D5 (e.g., the gate length of the assisting gate structure 212) and the dimension D6 (e.g., the gate length of the control gate structure 210) are approximately equal.

In some implementations, a thickness of the high-k portion 214a of the gate dielectric layer 214 is greater than a thickness of the gate dielectric layer 218. In some implementations, a thickness of the low-k portion 214b of the gate dielectric layer 214 is greater than a thickness of the gate dielectric layer 218.

FIG. 2G is a cross-sectional view of another example of a fin-based TFET structure 202 in a cross-sectional plane E in FIG. 2A. In this example, a capping layer 242 is included between the assisting gate structure 212 of the fin-based TFET structure 202 and the fin structure 206. The capping layer 242 may have a band gap that is less than the band gap of the fin structure 206. The capping layer 242 may include similar materials as the source/drain region 222 and may function to extend the control of the band bending in the valence band and/or conduction band over the source/drain region 222. For example, for a PTFET, the capping layer 242 may include a semiconductor material doped with one or more n-type dopants such as indium antimonide (InSb), gallium (Ga), and/or antimony (Sb), among other examples. As another example, for an NTFET, the capping layer 242 may include a semiconductor material doped with one or more p-type dopants such as germanium (Ge) and/or indium arsenide (InAs), among other examples. The doping concentration in the capping layer 242 may be greater than the doping concentration in the fin structure 206. For example, the doping concentration in the capping layer 242 may be at least 100 times greater than the doping concentration in the fin structure 206. However, other values are within the scope of the present disclosure. This enables a greater amount of band bending to be achieved, which may enable the assisting gate structure 212 to be operated with lesser assisting gate voltages than without the capping layer 242.

A detailed view of a layer stack along a line F-F between the assisting gate structure 212 and the fin structure 206 is further shown in FIG. 2G. Between the assisting gate structure 212 and the fin structure 206, the capping layer 242 is in contact with the fin structure 206, an interfacial layer 244 is included next to the capping layer 242, and the gate dielectric layer 218 is included next to the interfacial layer 244. The interfacial layer 244 may include a low-k dielectric layer such as silicon oxide (SiOₓ) and/or another suitable dielectric material.

The gate dielectric layer 218 may include a gate dielectric layer stack that includes a plurality of high-k dielectric layers, such as a high-k dielectric layer 246 and a high-k dielectric layer 248, among other examples. The high-k dielectric layer 246 may be included between the interfacial layer 244 and the high-k dielectric layer 248. The high-k dielectric layers 248 and 246 may each include one or more high-k dielectric materials such as a hafnium oxide (HfOₓ such as HfO₂), an aluminum oxide (AlₓO_{y} such as Al₂O₃), a lanthanum oxide (LaₓO_{y} such as La₂O₃), a yttrium oxide (YₓO_{y} such as Y₂O₃), and/or a hafnium lanthanum silicon oxide (HfLaSiOₓ), among other examples. Additionally and/or alternatively, the high-k dielectric layers 246 and/or 246 may include one or more dielectric materials that include silicon (Si), oxygen (O), hafnium (Hf), lanthanum (La), zirconium (Zr), zinc (Zn), and/or yttrium (Y), among other examples.

The materials of the high-k dielectric layers 246 and/or 246 may be selected such that an interface dipole is created between two or more layers between the fin structure 206 and the assisting gate structure 212. The interface dipole can be used to create a built-in electric field between the fin structure 206 and the assisting gate structure 212, and this built-in electric field can enable the assisting gate structure 212 to be operated with lesser assisting gate voltages. The interface dipole may be formed due to a difference in oxygen density between two or more layers between the fin structure 206 and the assisting gate structure 212. For example, and as shown in the example in FIG. 2H, an interface dipole may form between the high-k dielectric layers 248 and 246 of the gate dielectric layer 218 due to the difference in oxygen density. The difference in oxygen density may result in the formation of oxygen vacancies in one of the high-k dielectric layer 246 or the high-k dielectric layer 248, and these oxygen vacancies may act as charge traps, which results in the formation of the interface dipole and the associated built-in electric field.

A detailed view of a layer stack along a line G-G between the control gate structure 210 and the fin structure 206 is further shown in FIG. 2G. Between the control gate structure 210 and the fin structure 206, an interfacial layer 250 is included next to the fin structure 206, and the high-k portion 214a of the gate dielectric layer 214 is included next to the interfacial layer 250.

FIG. 2H illustrates a cross-sectional view along the line H-H in FIG. 2G of the example of the fin-based TFET structure 202 illustrated in FIG. 2G. As shown in FIG. 2H, the capping layer 242 wraps around the fin structure 206 on at least three sides of the fin structure 206. The gate dielectric layer 218 is included on the capping layer 242, and the gate electrode 220 is included on the gate dielectric layer 218. The width of the fin structure 206 (indicated n FIG. 2I as the dimension D3) includes the thickness of the capping layer 242.

FIG. 2I is a cross-sectional view of another example of a fin-based TFET structure 202 in a cross-sectional plane E in FIG. 2A. In this example, the position of the high-k dielectric layers 248 and 246 of the gate dielectric layer 218 are reversed relative to the example of the fin-based TFET structure 202 illustrated in FIG. 2G. Thus, the high-k dielectric layer 248 is next to the interfacial layer 244 and between the interfacial layer 244 and the high-k dielectric layer 246. In this configuration, the interface dipole may be formed between the interfacial layer 244 and the high-k dielectric layer 248. In some implementations, the example of the fin-based TFET structure 202 illustrated in FIG. 2G may be implemented as an NTFET, whereas the example of the fin-based TFET structure 202 illustrated in FIG. 2I may be implemented as a PTFET.

As indicated above, FIGS. 1 and 2A-21 are provided as examples. Other examples may differ from what is described with regard to FIGS. 1 and 2A-2I.

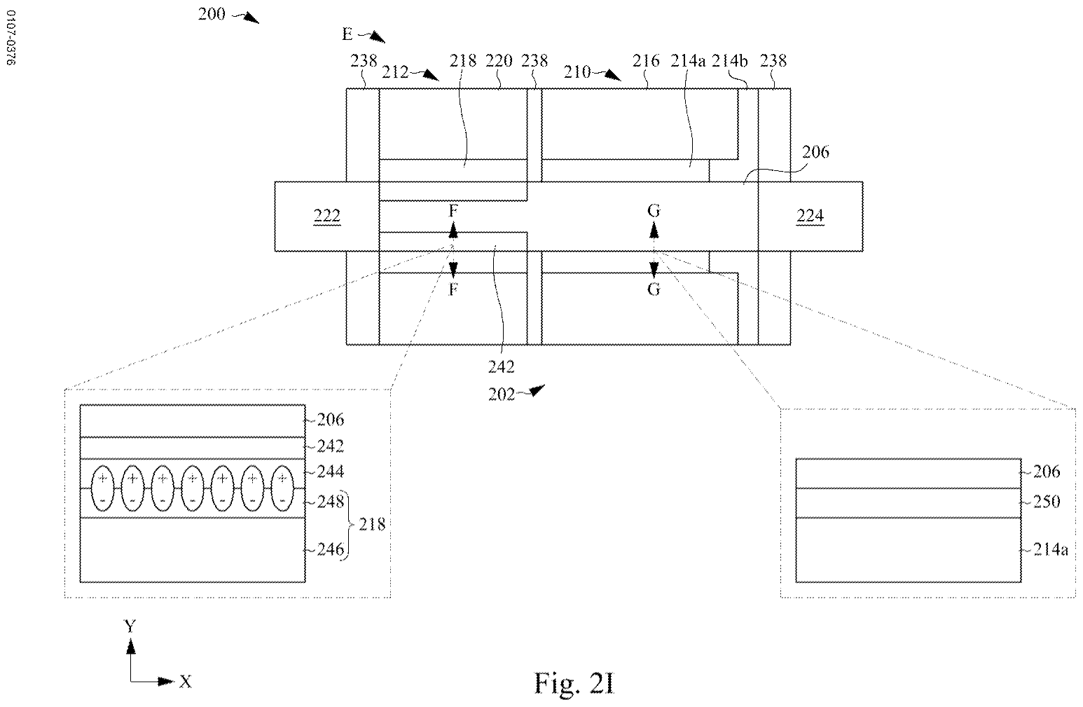

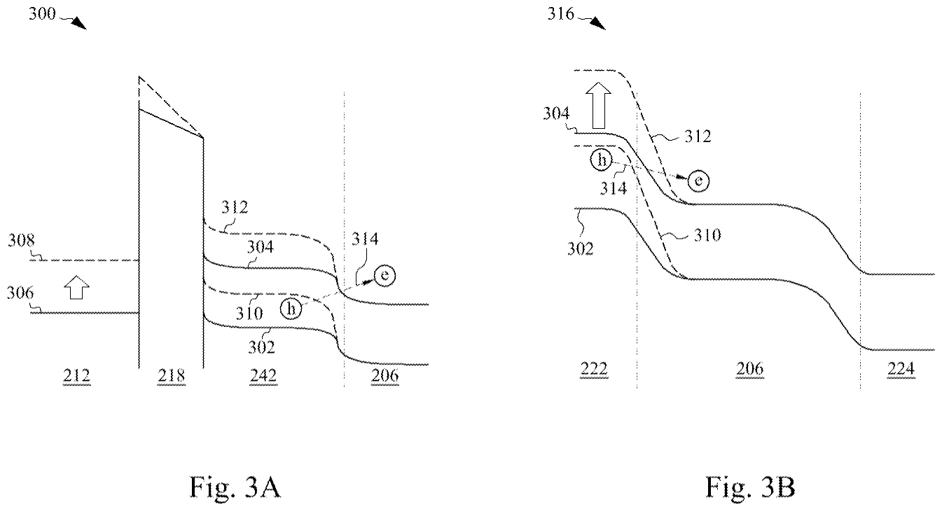

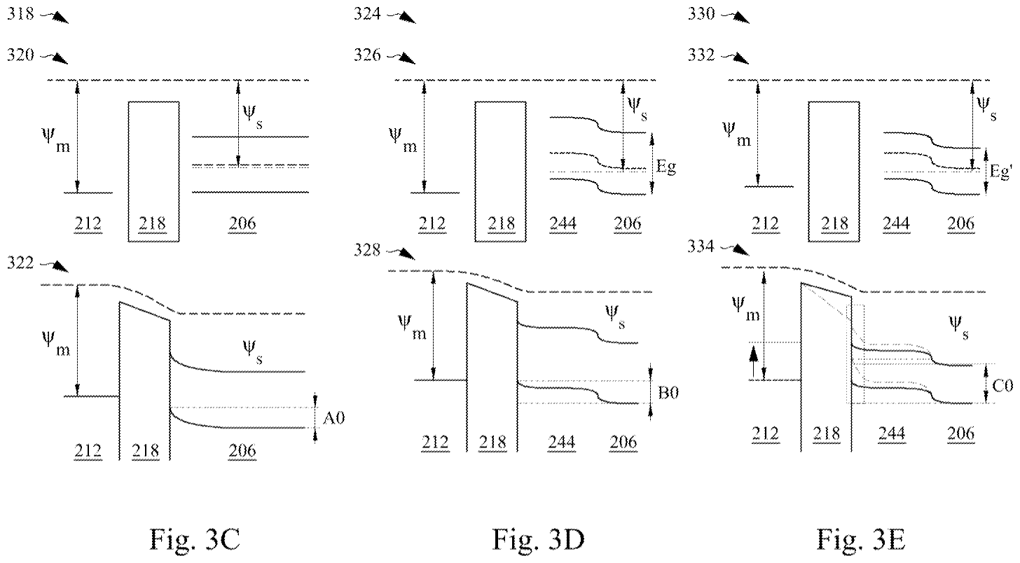

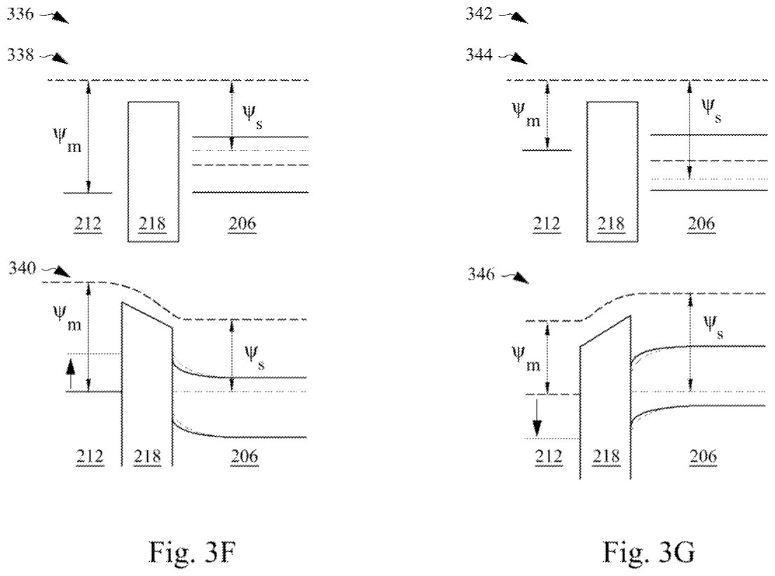

FIGS. 3A-3G are diagrams of examples of band diagrams for one or more of the example fin-based TFET structures 202 described herein. FIG. 3A illustrates an example band diagram 300 for various examples of fin-based TFET structures 202 illustrated and described in connection with FIGS. 2G-2I (e.g., the examples of fin-based TFET structures 202 that include a capping layer 242). The example band diagram 300 illustrates the valence band 302 and the conduction band 304 across the assisting gate structure 212, the gate dielectric layer 218, the capping layer 242, and the fin structure 206. As shown in FIG. 3A, a gate voltage 306 is increased to an assisting gate voltage 308 on the assisting gate structure 212. This causes the valence band 302 to be raised to a modified valence band 310 in the capping layer 242, and causes the conduction band 304 to be raised to a modified conduction band 312. The tunneling distance 314 between the capping layer 242 and the fin structure 206 is reduced as a result of the modified valence band 310 and the modified conduction band 312.

FIG. 3B illustrates an example band diagram 316 for various examples of fin-based TFET structures 202 illustrated and described in connection with FIGS. 2G-2I (e.g., the examples of fin-based TFET structures 202 that include a capping layer 242). The example band diagram 316 illustrates the valence band 302 and the conduction band 304 across the fin structure 206 between the source/drain region 222 and the source/drain region 224. As shown in FIG. 3B, the tunneling distance 314 between the source/drain region 222 and the fin structure 206 is reduced as a result of the modified valence band 310 and the modified conduction band 312 (e.g., as a result of the assisting gate voltage 308 being applied to the assisting gate structure 212).

FIG. 3C illustrates an example 318 of a band diagram 320 and a band diagram 322, respectively, illustrating the valance and conduction bands for a fin structure 206 prior to formation of an assisting gate structure 212 and illustrating the resulting band bending (indicated by A0 in FIG. 3C) after formation of a fin-based TFET structure 202 with one or more work function tuning metals included in the gate electrode 220 of the assisting gate structure 212.

FIG. 3D illustrates an example 324 of a band diagram 326 and a band diagram 328, respectively, illustrating the valance and conduction bands for a fin structure 206 prior to formation of an assisting gate structure 212 and an associated capping layer 242, and illustrating the resulting band bending that results after formation of the assisting gate structure 212 and the associated capping layer 242 (indicated by BO in FIG. 3D). BO may be greater than A0.

FIG. 3E illustrates an example 330 of a band diagram 332 and a band diagram 334, respectively, illustrating the valance and conduction bands for a fin structure 206 prior to formation of an assisting gate structure 212 and an associated capping layer 242 having a band gap that is smaller than the fin structure 206, and illustrating the resulting band bending after formation of the assisting gate structure 212 and the associated capping layer 242 having a band gap that is smaller than the fin structure (indicated by C0 in FIG. 3D). C0 may be greater than B0 and A0. In other words, the band gap of the material of the capping layer 242 is less than the band gap of the material of the fin structure 206 in the example 330.

FIG. 3F illustrates an example 336 of a band diagram 338 and a band diagram 340, respectively, illustrating no band bending for an NTFET-type fin-based TFET structure without a gate dielectric layer stack having a plurality of high-k dielectric layers for forming an interface dipole, and illustrating the resulting band bending for an NTFET-type fin-based TFET structure 202 with a gate dielectric layer stack having a plurality of high-k dielectric layers 246, 246 for forming an interface dipole.

FIG. 3G illustrates an example 342 of a band diagram 344 and a band diagram 346, respectively, illustrating no band bending for a PTFET-type fin-based TFET structure without a gate dielectric layer stack having a plurality of high-k dielectric layers for forming an interface dipole, and illustrating the resulting band bending for an PTFET-type fin-based TFET structure 202 with a gate dielectric layer stack having a plurality of high-k dielectric layers 246, 248 for forming an interface dipole.

As indicated above, FIGS. 3A-3G are provided as examples. Other examples may differ from what is described with regard to FIGS. 3A-3G.

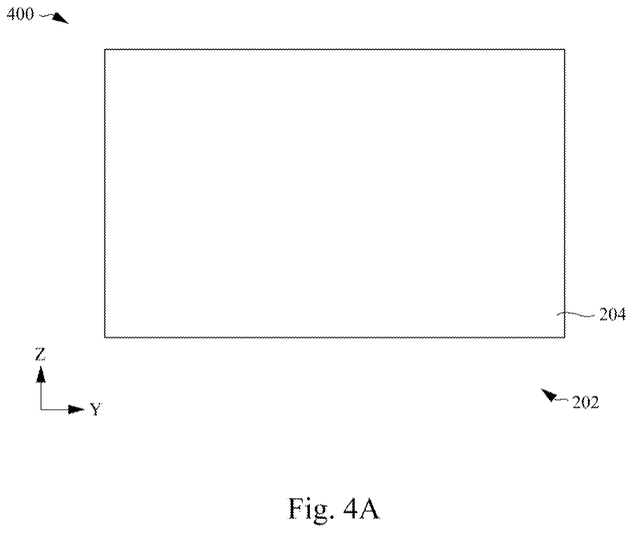

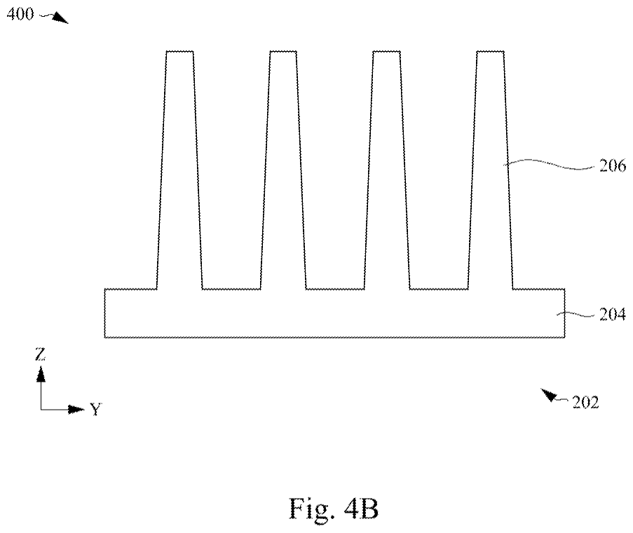

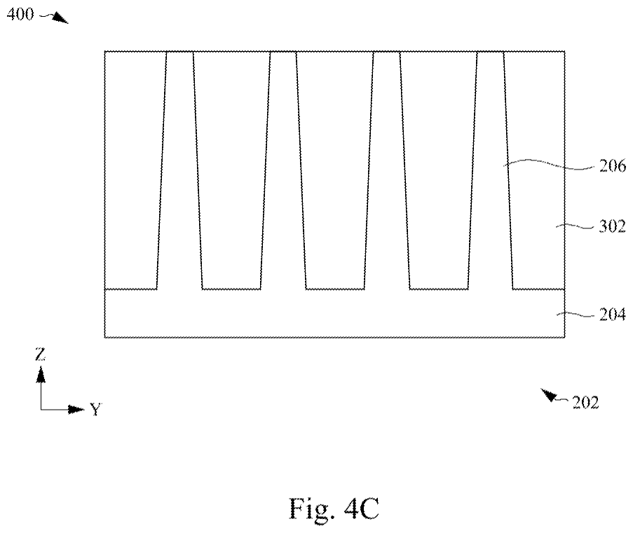

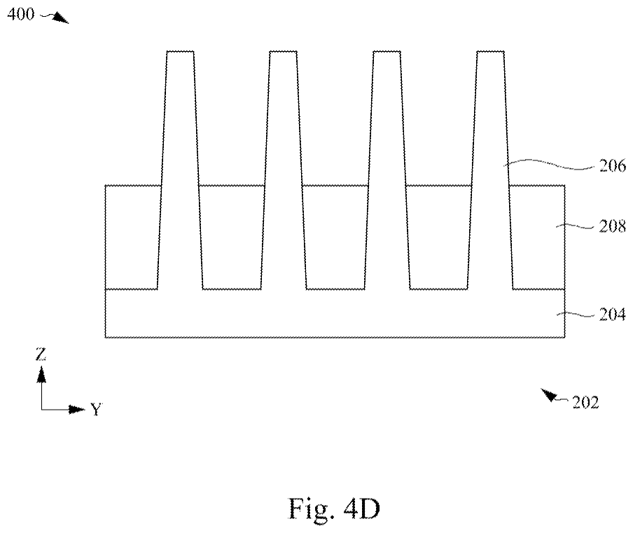

FIGS. 4A-4D are diagrams of an example 400 of forming fin structures 206 in a semiconductor device 200 described herein. The example 400 includes an example of forming fin structures 206 for a fin-based TFET structure 202 of the semiconductor device 200. In some implementations, one or more of the operations described in connection with FIGS. 4A-4D are performed using one or more semiconductor processing tools and/or a wafer/die transport tool. Turning to FIG. 4A, the example 400 includes semiconductor processing operations relating to the substrate 204 in and/or on which the fin-based TFET structure 202 is formed.

As shown in FIG. 4B, the fin structures 206 are formed in the substrate 204. In some implementations, a pattern in a photoresist layer is used to form the fin structures 206. In these implementations, a deposition tool is used to form the photoresist layer on the substrate 204. An exposure tool is used to expose the photoresist layer to a radiation source to pattern the photoresist layer. A developer tool is used to develop and remove portions of the photoresist layer to expose the pattern. An etch tool is used to etch into the substrate 204 to form the fin structures 206. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the fin structures 206 based on a pattern.

As shown in FIG. 4C, an STI layer 302 is formed in between the fin structures 206. A deposition tool is used to deposit the STI layer 302 using a CVD technique, a PVD technique, an ALD technique, and/or another deposition technique. In some implementations, the STI layer 302 is formed to a height that is greater than the height of the fin structures 206. In these implementations, a planarization tool is used to perform a planarization (or polishing) operation to planarize the STI layer 402 such that the top surface of the STI layer 302 is substantially flat and smooth, and such that the top surface of the STI layer 302 and the top surface of the fin structures 206 are approximately the same height. The planarization operation may increase uniformity in the STI regions 208 that are formed from the STI layer 302 in a subsequent etch-back operation.

As shown in FIG. 4D, the STI layer 302 is etched in an etch back operation to expose portions of the fin structures 206. An etch tool is used to etch a portion of the STI layer 302 using a plasma etch technique, a wet chemical etch technique, and/or another type of etch technique. The remaining portions of the STI layer 302 between the fin structures 206 include the STI regions 208. In some implementations, the STI layer 302 is etched such that the height of the exposed portions of the fin structures 206 (e.g., the portions of the fin structures 206 that are above the top surface of the STI regions 208) are the same height. In some implementations, a first portion of the STI layer 302 is etched and a second portion of the STI layer 302 is etched such that the height of exposed portions of a first subset of the fin structures 206 and the height of the exposed portions of a second subset of the fin structures 206 are different.

As indicated above, FIGS. 4A-4D are provided as an example. Other examples may differ from what is described with regard to FIGS. 4A-4D.

FIGS. 5A and 5B are diagrams of an example 500 of forming a capping layer 242 in a semiconductor device 200 described herein. The example 500 includes an example of forming a capping layer 242 on a fin structure 206 of a fin-based TFET structure 202 of the semiconductor device 200. In some implementations, one or more of the operations described in connection with FIGS. 5A and 5B are performed using one or more semiconductor processing tools and/or a wafer/die transport tool.

Turning to FIG. 5A, one or more of the operations described in connection with FIGS. 5A and 5B are performed after one or more of the operations described in connection with FIGS. 4A-4D. As shown in FIG. 5B, the capping layer 242 is formed on the fin structure 206 such that the capping layer 242 is included on the top surface and on the sidewalls of the fin structure 206. In some implementations, a deposition tool is used to conformally deposit the capping layer 242 such that the capping layer 242 conforms to the profile of the fin structure 206. A conformal deposition technique such as ALD may be used. In some implementations, a deposition tool is used to grow the capping layer 242 on the fin structure 206 using an epitaxy technique. In some implementations, another deposition technique such as CVD is used to deposit the capping layer 242.

As indicated above, FIGS. 5A and 5B are provided as an example. Other examples may differ from what is described with regard to FIGS. 5A and 5B.

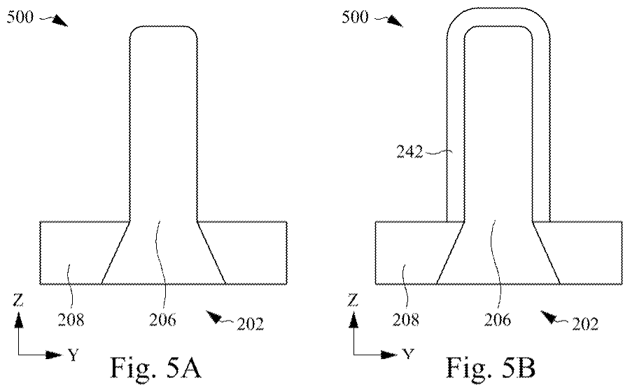

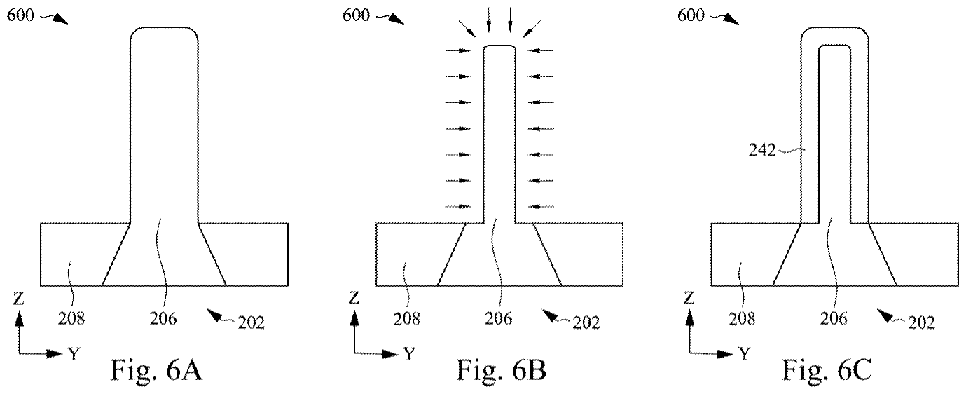

FIGS. 6A-6C are diagrams of an example 600 of forming a doped semiconductor capping layer 242 in a semiconductor device 200 described herein. The example 600 includes an example of forming a doped semiconductor capping layer 242 on a fin structure 206 of a fin-based TFET structure 202 of the semiconductor device 200. In some implementations, one or more of the operations described in connection with FIGS. 6A-6C are performed using one or more semiconductor processing tools and/or a wafer/die transport tool.

Turning to FIG. 6A, one or more of the operations described in connection with FIGS. 6A-6C are performed after one or more of the operations described in connection with FIGS. 4A-4D. As shown in FIG. 6B, a fin trimming operation is performed to remove material from the fin structure 206. The fin trimming operation may be performed to reduce the size of the fin structure 206 in preparation for forming the capping layer 242 on the fin structure 206. In some implementations, an etch tool is used to perform the fin trimming using a dry etch technique, a wet etch technique, and/or another etch technique.

As shown in FIG. 6C, the capping layer 242 is formed on the fin structure 206 after the fin trimming operation described in connection with FIG. 6B. The capping layer 242 is formed such that the capping layer 242 is included on the top surface and on the sidewalls of the fin structure 206. In some implementations, a deposition tool is used to conformally deposit the capping layer 242 such that the capping layer 242 conforms to the profile of the fin structure 206. A conformal deposition technique such as ALD may be used. In some implementations, a deposition tool is used to grow the capping layer 242 on the fin structure 206 using an epitaxy technique. In some implementations, another deposition technique such as CVD is used to deposit the capping layer 242.

As indicated above, FIGS. 6A-6C are provided as an example. Other examples may differ from what is described with regard to FIGS. 6A-6C.

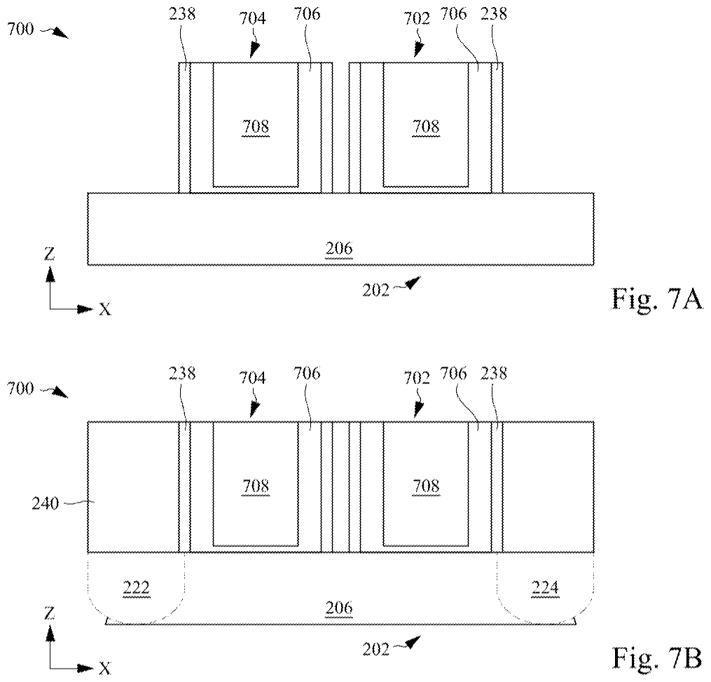

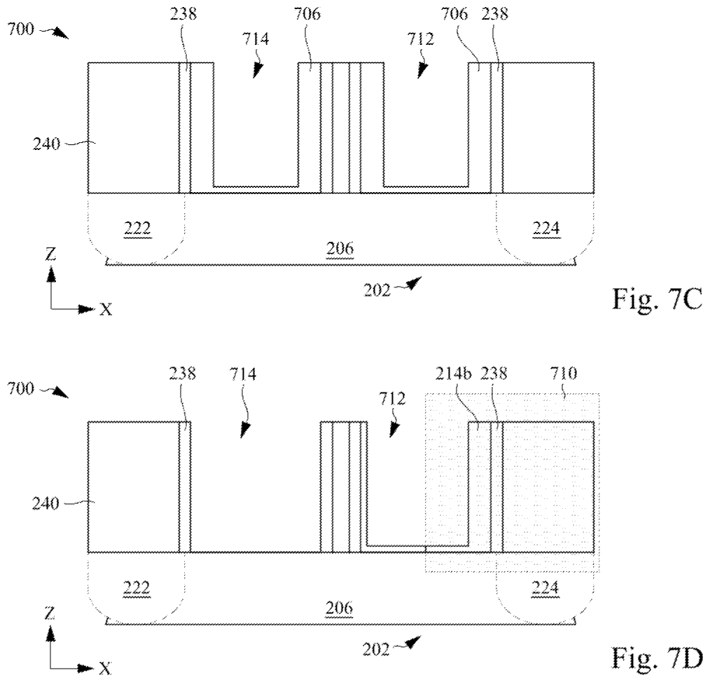

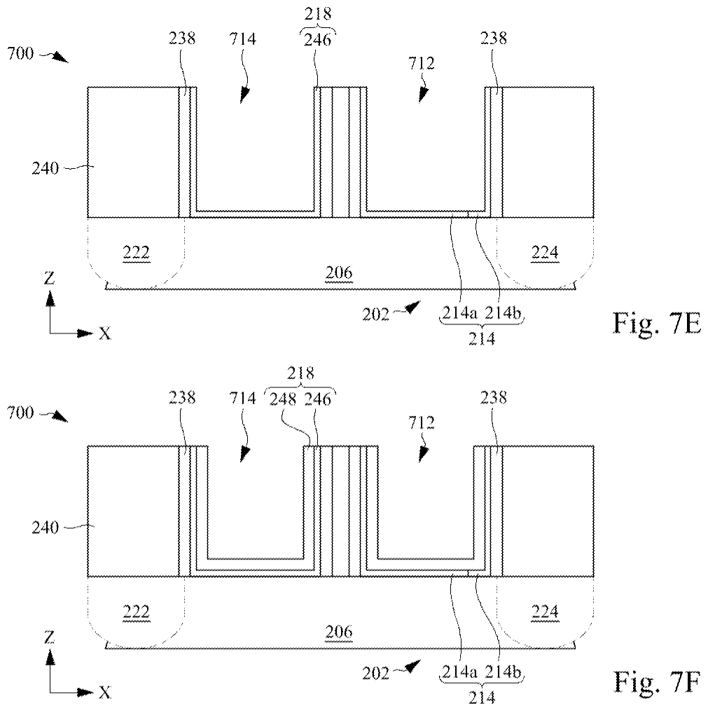

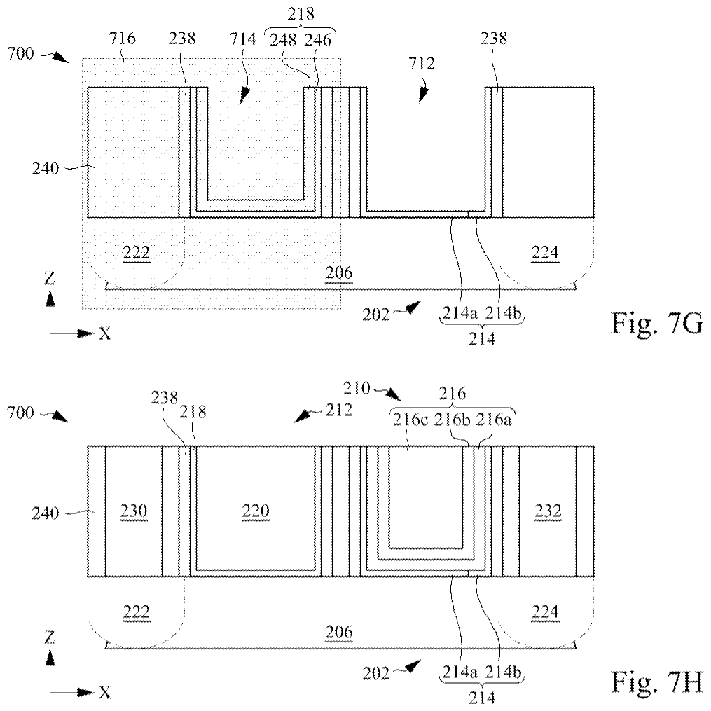

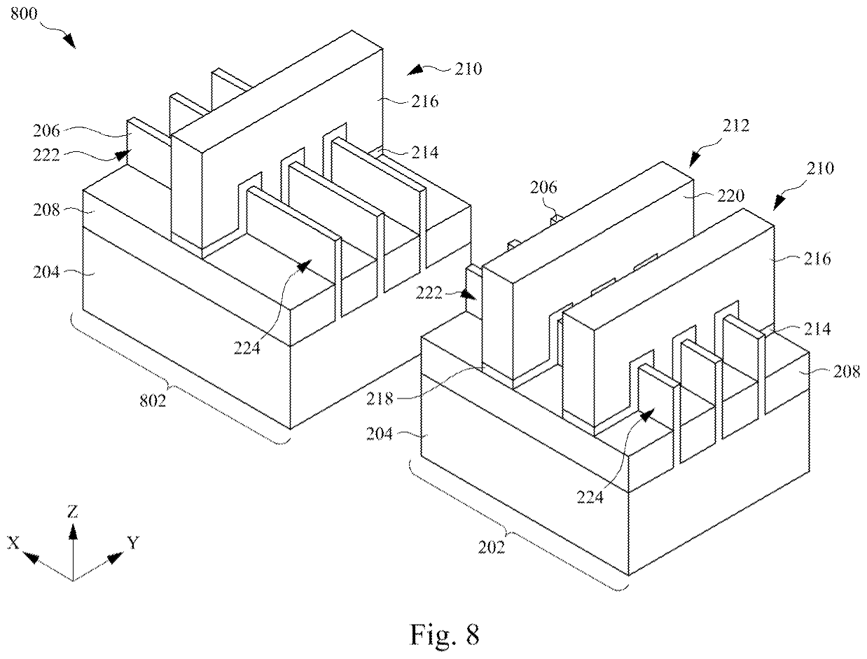

FIGS. 7A-7H are diagrams of an example 700 of forming a fin-based TFET structure 202 of the semiconductor device 200. In some implementations, one or more of the operations described in connection with FIGS. 7A-7H are performed using one or more semiconductor processing tools and/or a wafer/die transport tool. In some implementations, one or more of the operations described in connection with FIGS. 7A-7H are performed after one or more of the operations described in connection with FIGS. 4A-4D, 5A, 5B, and/or 6A-6C, among other examples.

As shown in FIG. 7A, dummy gate structures 702 and 704 may be formed on a fin structure 206 for the fin-based TFET structure 202. The dummy gate structures 702 and 704 are formed and included over the fin structures 206, and around the sides of the fin structures 206 such that the dummy gate structures 702 and 704 surround the fin structure 206 on at least three sides of the fin structure 206. The dummy gate structures 702 and 704 are formed as placeholders for the control gate structure 210 and the assisting gate structure 212 of the fin-based TFET structure 202. The dummy gate structures 702 and 704 may be formed as part of a replacement gate process, which enables other layers and/or structures to be formed prior to formation of the control gate structure 210 and the assisting gate structure 212.

The dummy gate structures 702 and 704 may each include a gate dielectric layer 706 and a gate electrode 708. The gate dielectric layers 706 may each include dielectric oxide layers. As an example, the gate dielectric layers 706 may each be formed (e.g., using a deposition tool) by chemical oxidation, thermal oxidation, ALD, CVD, and/or other suitable methods. The gate electrodes 708 may each include a polysilicon layer or other suitable layers. For example, the gate electrodes 708 may be formed (e.g., using the deposition tool 102) by suitable deposition processes such as LPCVD or PECVD, among other examples.

As further shown in FIG. 7A, the gate spacers 238 may be formed on the sidewalls of the dummy gate structures 702 and 704. In some implementations, the gate spacers 238 are conformally deposited (e.g., using a deposition tool) on the dummy gate structures 702 and 704, and on the fin structures 206. The gate spacers 238 are then patterned (e.g., using a deposition tool, an exposure tool 104, and/or a developer tool 106) and etched (e.g., using an etch tool) to remove the material of the gate spacers 238 from the tops of the dummy gate structures 702 and 704, and from the fin structures 206.

As shown in FIG. 7B, the source/drain regions 222 and 224 are formed in and/or on the fin structure 206. The source/drain region 222 may be formed adjacent to a first side of the dummy gate structure 704 that is opposing a second side of the dummy gate structure 704 facing the dummy gate structure 702. The source/drain region 224 may be formed adjacent to a first side of the dummy gate structure 702 that is opposing a second side of the dummy gate structure 702 facing the dummy gate structure 704.

In some implementations, recesses are formed in the fin structure 206, and the source/drain regions 222 and 224 are formed in the recesses. The etch operation may be referred to as a strained source/drain (SSD) etch operation, and the recesses may be referred to as strained source/drain recesses. In some implementations, the etch operation includes a plasma etch technique, a wet chemical etch technique, and/or another type of etch technique.

The source/drain regions 222 and 224 may then be formed in the recesses. A deposition tool may be used to form the source/drain regions 222 and 224 in one or more epitaxy operations, in which layers of the epitaxial material are deposited in the recesses such that the layers of p-doped semiconductor material and/or layers of n-doped semiconductor material are formed by epitaxial growth in a particular crystalline orientation.

In some implementations, the source/drain regions 222 and 224 are formed sequentially. For example, the source/drain region 222 may be formed first (e.g., while the area of the fin structure 206 in which the source/drain region 224 is to be formed is masked), followed by the formation of the source/drain region 224.

As further shown in FIG. 7B, the dielectric layer 240 is formed over the source/drain regions 222 and 224. A deposition tool may be used to deposit the dielectric layer 240 using a PVD technique, an ALD technique, a CVD technique, an oxidation technique, and/or another suitable deposition technique. The dielectric layer 240 may be deposited in one or more deposition operations. In some implementations, a planarization tool may be used to planarize the dielectric layer 240 after the dielectric layer 240 is deposited. In some implementations, the dielectric layer 240 is planarized such that the top surface of the dielectric layer 240 is co-planar with the tops of the dummy gate structures 702 and 704. In this way, the tops of the dummy gate structures 702 and 704 are exposed through the dielectric layer 240.

As shown in FIGS. 7C and 7D, the dummy gate structures 702 and 704 are removed (e.g., after formation of the source/drain regions 222 and 224). Removal of the dummy gate structures 702 and 704 results in formation of recesses 712 and 714, respectively. As shown in FIG. 7C, the gate electrodes 708 of the dummy gate structures 702 and 704 may be removed. In some implementations, an etch tool is used to remove the gate electrodes 708 (e.g., using a dry etch technique, using a wet etch technique).

As shown in FIG. 7D, the gate dielectric layer 706 may be removed from the recess 714 left behind by the dummy gate structure 704. A portion of the gate dielectric layer 706 may be removed from the recess 712 left behind by the dummy gate structure 702. However, another portion remains in the recess 712 as the low-k portion 214b of the control gate structure 210.

In some implementations, a pattern in a photoresist layer 710 is used to remove the gate dielectric layer 706 from the recess 714 and to remove the portion of the gate dielectric layer 706 from the recess 712. In these implementations, a deposition tool may be used to form the photoresist layer 710. An exposure tool may be used to expose the photoresist layer 710 to a radiation source to pattern the photoresist layer 710. A developer tool may be used to develop and remove portions of the photoresist layer 710 to expose the pattern. An etch tool may be used to etch the gate dielectric layers 706 in the recesses 712 and 714 based on the pattern to remove the gate dielectric layer 706 from the recess 714 and to form the low-k portion 214b in the recess 712. In some implementations, the etch operation includes a plasma etch operation, a wet chemical etch operation, and/or another type of etch operation. In some implementations, a photoresist removal tool may be used to remove the remaining portions of the photoresist layer 710 (e.g., using a chemical stripper, plasma ashing, and/or another technique). In some implementations, a hard mask layer is used as an alternative technique for etching the gate dielectric layers 706 based on a pattern.

As shown in FIG. 7E, the high-k portion 214a of the gate dielectric layer 214 is formed in the recess 712 for the control gate structure 210. The high-k dielectric layer 246 of the gate dielectric layer 218 is formed in the recess 714 for the assisting gate structure 212. A deposition tool may be used to deposit the high-k portion 214a of the gate dielectric layer 214 and/or the high-k dielectric layer 246 of the gate dielectric layer 218 using a PVD technique, an ALD technique, a CVD technique, an oxidation technique, and/or another suitable deposition technique. In some implementations, the deposition tool 102 may be used to deposit the high-k portion 214a of the gate dielectric layer 214 and the high-k dielectric layer 246 of the gate dielectric layer 218 are conformally deposited such that the high-k portion 214a of the gate dielectric layer 214 and the high-k dielectric layer 246 of the gate dielectric layer 218 respectively conform to a profile of the recess 712 and the profile of the recess 714.

As shown in FIG. 7F, the high-k dielectric layer 248 is formed in the recesses 712 and 714. The high-k dielectric layer 248 is formed on the gate dielectric layer 214 in the recess 712. The high-k dielectric layer 248 is formed on the high-k dielectric layer 246 in the recess 714. A deposition tool may be used to deposit the high-k dielectric layer 248 using a PVD technique, an ALD technique, a CVD technique, an oxidation technique, and/or another suitable deposition technique. In some implementations, a deposition tool may be used to conformally deposit the high-k dielectric layer 248 such that the high-k dielectric layer 248 conforms to the profile of the recess 712 and the profile of the recess 714.

As shown in FIG. 7G, a photoresist layer 716 is formed over the recess 714 such that the high-k dielectric layer 248 can be removed from the recess 712 without removing the high-k dielectric layer 248 from the recess 714. The high-k dielectric layer 248 remains in the recess 714 as part of the gate dielectric layer stack of the gate dielectric layer 218. In some implementations, a thermal operation may also be performed to anneal the high-k dielectric layers 248 and 246 (e.g., to facilitate formation of the interface dipole in the gate dielectric layer 218.

In some implementations, a pattern in the photoresist layer 716 is used to remove the high-k dielectric layer 248 from the recess 712. In these implementations, a deposition tool may be used to form the photoresist layer 716. An exposure tool may be used to expose the photoresist layer 716 to a radiation source to pattern the photoresist layer 716. A developer tool may be used to develop and remove portions of the photoresist layer 716 to expose the pattern. A etch tool may be used to etch the high-k dielectric layer 248 in the recesses 712 based on the pattern to remove the high-k dielectric layer 248 from the recess 712. In some implementations, the etch operation includes a plasma etch operation, a wet chemical etch operation, and/or another type of etch operation. In some implementations, a photoresist removal tool may be used to remove the remaining portions of the photoresist layer 716 (e.g., using a chemical stripper, plasma ashing, and/or another technique). In some implementations, a hard mask layer is used as an alternative technique for removing the high-k dielectric layer 248 from the recess 712.

As shown in FIG. 7H, the gate electrode 216 of the control gate structure 210 may be formed in the recess 712, and the gate electrode 220 of the assisting gate structure 212 may be formed in the recess 714. The gate electrode 216 of the control gate structure 210 is formed on the gate dielectric layer 214 (e.g., on the high-k portion 214a and the low-k portion 214b of the gate dielectric layer 214) in the recess 712. Forming the gate electrode 216 may include forming the gate electrode layer 216a on the gate dielectric layer 214 in the recess 712, forming the gate electrode layer 216b on the gate electrode layer 216a, and forming the gate electrode layer 216c on the gate electrode layer 216b, among other examples.

A deposition tool may be used to deposit the gate electrode 216 (e.g., the gate electrode layers 216a-216c) using a CVD technique, a PVD technique, an ALD technique, an electroplating technique, and/or another suitable deposition technique. The gate electrode 216 (e.g., the gate electrode layers 216a-216c) may be deposited in one or more deposition operations. In some implementations, a seed layer is first deposited, and the gate electrode 216 (or one or more of the gate electrode layers 216a-216c) is deposited on the seed layer. In some implementations, a planarization tool may be used to planarize the gate electrode 216 (or one or more of the gate electrode layers 216a-216c).

The gate electrode 220 of the assisting gate structure 212 is formed on the gate dielectric layer 218 (e.g., on the high-k dielectric layer 246 on the high-k dielectric layer 248) in the recess 714. A deposition tool may be used to deposit the gate electrode 220 using a CVD technique, a PVD technique, an ALD technique, an electroplating technique, and/or another suitable deposition technique. The gate electrode 220 may be deposited in one or more deposition operations. In some implementations, a seed layer is first deposited, and the gate electrode 220 is deposited on the seed layer. In some implementations, a planarization tool may be used to planarize the gate electrode 220.

As further shown in FIG. 7H, the source/drain contacts 230 and 232 may be respectively formed on the source/drain region 222 and the source/drain region 224. To form the source/drain contacts 230 and 232, recesses may be formed in the dielectric layer 240 above the source/drain regions 222 and 224 such that the source/drain regions 222 and 224 are exposed through the recesses.

In some implementations, a pattern in a photoresist layer is used to etch the dielectric layer 240 to form the recesses. In these implementations, a deposition tool may be used to form the photoresist layer on the dielectric layer 240. An exposure tool may be used to expose the photoresist layer to a radiation source to pattern the photoresist layer. A developer tool may be used to develop and remove portions of the photoresist layer to expose the pattern. An etch tool may be used to etch the dielectric layer 240 based on the pattern to form the recesses in the dielectric layer 240. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 240 based on a pattern.

A deposition tool may be used to deposit the source/drain contacts 230 and/or 232 in the recesses using a CVD technique, a PVD technique, an ALD technique, an electroplating technique, and/or another suitable deposition technique. The source/drain contacts 230 and/or 232 may be deposited in one or more deposition operations. In some implementations, a seed layer is first deposited, and the source/drain contacts 230 and/or 232 are deposited on the seed layer. In some implementations, a planarization tool may be used to planarize the source/drain contacts 230 and/or 232 after the source/drain contacts 230 and/or 232 are deposited.

As indicated above, FIGS. 7A-7H are provided as an example. Other examples may differ from what is described with regard to FIGS. 7A-7H.

FIG. 8 is a diagram of an example of a semiconductor device 800 described herein. The semiconductor device 800 is similar to the semiconductor device 200, except that the semiconductor device 800 includes a plurality of types of fin-based TFET structures. For example, the semiconductor device 800 includes a fin-based TFET structure 202 and a fin-based TFET structure 802. The fin-based TFET structure 202 may be manufactured according to one or more of the example fin-based TFET structure configurations illustrated and described herein. The fin-based TFET structure 802 is similar to the fin-based TFET structure 202, except that the assisting gate structure 212 is omitted. This enables different types of fin-based TFET structures to be integrated onto the same semiconductor device 800.

As indicated above, FIG. 8 is provided as an example. Other examples may differ from what is described with regard to FIG. 8.

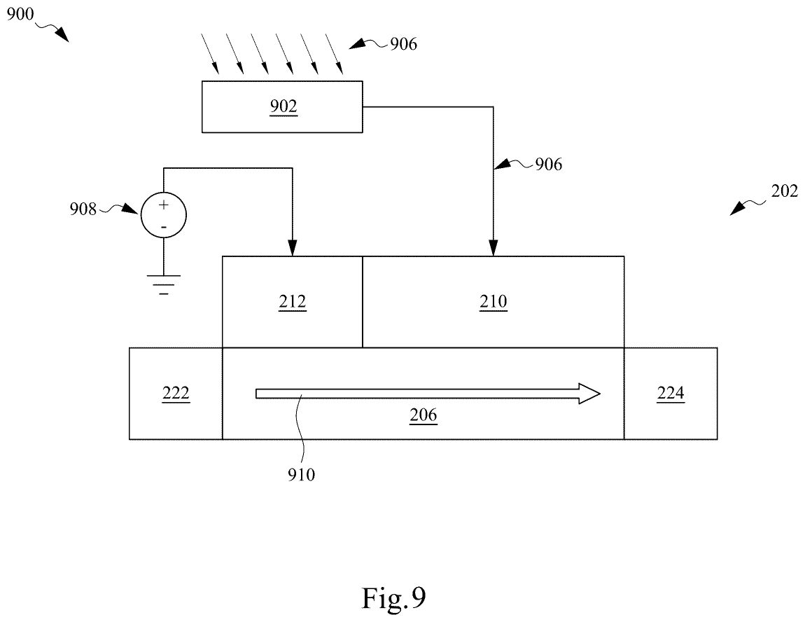

FIG. 9 is a diagram of an example of a semiconductor device 900 described herein. The semiconductor device 900 includes a fin-based TFET structure 202 coupled with a sensor device 902. The sensor device 902 includes a photodiode, a stress sensor or strain gauge, a temperature sensor, a biomolecular sensor, and/or another type of sensor that generates a small electrical signal 904 based on an input 906. The input 906 may be an optical signal (e.g., light, a laser signal), a temperature, vibration, ultrasound, and/or another type of input. The small electrical signal 904 is used to operate the control gate structure 210 of the fin-based TFET structure 202 to switch the fin-based TFET structure 202 between an on and off state. The assisting gate structure 212 may be coupled to a voltage input 908, which applies an assisting gate voltage input to the assisting gate structure 212 to enable the small electrical signal 904 to operate the control gate structure 210. When the fin-based TFET structure 202 is switched on, charge carriers 910 may flow from the source/drain region 222 to the source/drain region 224 through the fin structure 206 (e.g., the channel region) by quantum tunneling. This enables the fin-based TFET structure 202 to operate an amplifier for the small electrical signal 904 generated by the sensor device 902.

As indicated above, FIG. 9 is provided as an example. Other examples may differ from what is described with regard to FIG. 9.

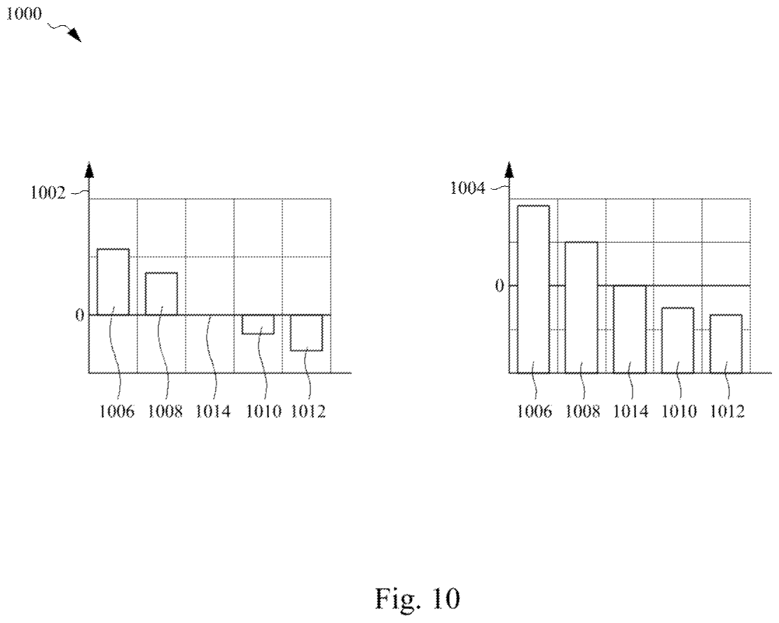

FIG. 10 is a diagram of examples 1000 of dielectric materials that may be used in a gate dielectric layer stack of a fin-based TFET structure 202 described herein. FIG. 10 further illustrates a flat-band voltage shift (V_{FB} shift) 1002 and a normalized areal oxygen density 1004 for the dielectric materials. The flat-band voltage shift 1002 is the flat-band voltage shift due to the interface dipole between the one or more layers in the gate dielectric stack, such as between an interfacial layer 244 and a high-k dielectric layer 248 or 246. The normalized areal oxygen density 1004 (σ/σ_{SiO2}) is the areal oxygen density (σ) of each of the dielectric materials, as normalized relative to the areal oxygen density of silicon dioxide (σ_{SiO2}). The dielectric materials may include aluminum oxide (Al₂O₃) 1006, hafnium oxide (HfO₂) 1008, yttrium oxide (Y₂O₃) 1010, and lanthanum oxide (La₂O₃) 1012. Silicon dioxide (SiO₂) 1014 is also illustrated for reference, as an example material that may be used for the interfacial layer 244.

As shown in FIG. 10, dielectric materials such as aluminum oxide 1006 and hafnium oxide 1008 may exhibit a positive flat-band voltage shift 1002. Moreover, aluminum oxide 1006 and hafnium oxide 1008 may have a greater areal oxygen density than silicon dioxide 1014, and thus have a positive normalized areal oxygen density 1004. Thus, dielectric materials such as aluminum oxide 1006 and hafnium oxide 1008 may be implemented in a gate dielectric layer stack for an NTFET, where the interface dipole may be formed between high-k dielectric layers 248 and 246 that respectively include hafnium oxide 1008 and aluminum oxide 1006. The interface dipole may enable lower assisting gate voltages to be used for the assisting gate structure 212 for NTFETs.

Dielectric materials such as yttrium oxide 1010 and lanthanum oxide 1012 (as well as hafnium lanthanum silicon oxide (HfLaSiOₓ) may exhibit a negative flat-band voltage shift 1002. Moreover, yttrium oxide 1010 and lanthanum oxide 1012 may have a lesser areal oxygen density than silicon dioxide 1014, and thus have a negative normalized areal oxygen density 1004. Thus, dielectric materials such as yttrium oxide 1010 and lanthanum oxide 1012 may be implemented in a gate dielectric layer stack for a PTFET, where the interface dipole may be formed between the interfacial layer 244 and one or more of the high-k dielectric layers 248 and 246. The interface dipole may enable lower assisting gate voltages to be used for the assisting gate structure 212 for PTFETs.

As indicated above, FIG. 10 is provided as examples. Other examples may differ from what is described with regard to FIG. 10.

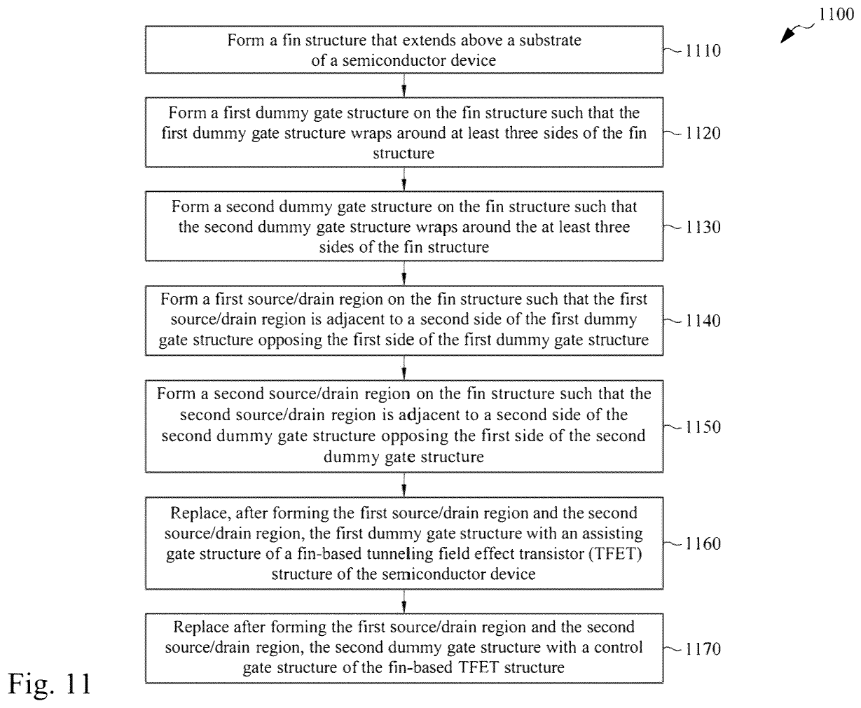

FIG. 11 is a flowchart of an example process 1100 associated with forming a semiconductor device described herein. In some implementations, one or more process blocks of FIG. 11 are performed using one or more semiconductor processing tools, such as a deposition tool, an exposure tool, a developer tool, an etch tool, a planarization tool, an ion implantation tool, and/or a wafer/die transport tool, among other examples. As shown in FIG. 11, process 1100 may include forming a fin structure that extends above a substrate of a semiconductor device (block 1110). For example, one or more semiconductor processing tools may be used to form a fin structure 206 that extends above a substrate 204 of a semiconductor device 200, as described herein. In some implementations, the fin structure comprises an intrinsic semiconductor material.

As further shown in FIG. 11, process 1100 may include forming a first dummy gate structure on the fin structure such that the first dummy gate structure wraps around at least three sides of the fin structure (block 1120). For example, one or more semiconductor processing tools may be used to form a dummy gate structure 704 on the fin structure 206 such that the dummy gate structure 704 wraps around at least three sides of the fin structure 206, as described herein.

As further shown in FIG. 11, process 1100 may include forming a second dummy gate structure on the fin structure such that the second dummy gate structure wraps around the at least three sides of the fin structure (block 1130). For example, one or more semiconductor processing tools may be used to form a dummy gate structure 702 on the fin structure 206 such that the dummy gate structure 702 wraps around the at least three sides of the fin structure 206, as described herein. In some implementations, a first side of the dummy gate structure 704 is adjacent to a first side of the dummy gate structure 702.

As further shown in FIG. 11, process 1100 may include forming a first source/drain region on the fin structure such that the first source/drain region is adjacent to a second side of the first dummy gate structure opposing the first side of the first dummy gate structure (block 1140). For example, one or more semiconductor processing tools may be used to form a source/drain region 222 on the fin structure 206 such that the source/drain region 222 is adjacent to a second side of the dummy gate structure 704 opposing the first side of the dummy gate structure 704, as described herein. In some implementations, the source/drain region 222 includes a first doped semiconductor material having a first dopant type.

As further shown in FIG. 11, process 1100 may include forming a second source/drain region on the fin structure such that the second source/drain region is adjacent to a second side of the second dummy gate structure opposing the first side of the second dummy gate structure (block 1150). For example, one or more semiconductor processing tools may be used to form a source/drain region 224 on the fin structure 206 such that the source/drain region 224 is adjacent to a second side of the dummy gate structure 702 opposing the first side of the dummy gate structure 702, as described herein. In some implementations, the source/drain region 224 includes a second doped semiconductor material having a second dopant type different from the first dopant type.

As further shown in FIG. 11, process 1100 may include replacing, after forming the first source/drain region and the second source/drain region, the first dummy gate structure with an assisting gate structure of a fin-based TFET structure of the semiconductor device (block 1160). For example, one or more semiconductor processing tools may be used to replace, after forming the source/drain region 222 and the source/drain region 224, the dummy gate structure 704 with an assisting gate structure 212 of a fin-based TFET structure 202 of the semiconductor device 200, as described herein.

As further shown in FIG. 11, process 1100 may include replacing, after forming the first source/drain region and the second source/drain region, the second dummy gate structure with a control gate structure of the fin-based TFET structure (block 1170). For example, one or more semiconductor processing tools may be used to replace, after forming the source/drain region 222 and the source/drain region 224, the dummy gate structure 702 with a control gate structure 210 of the fin-based TFET structure 202, as described herein.

Process 1100 may include additional implementations, such as any single implementation or any combination of implementations described below and/or in connection with one or more other processes described elsewhere herein.

In a first implementation, forming the dummy gate structure 704 includes forming a low-k gate dielectric layer (e.g., a gate dielectric layer 706) of the dummy gate structure 704, and forming a polysilicon gate electrode (e.g., a gate electrode 708) of the dummy gate structure 704, and replacing the dummy gate structure 704 with the assisting gate structure 212 includes removing the low-k gate dielectric layer and the polysilicon gate electrode, where removing the low-k gate dielectric layer and the polysilicon gate electrode results in formation of a recess 714, and forming, in the recess a high-k gate dielectric layer (e.g., a gate dielectric layer 218), and a metal gate electrode (e.g., a gate electrode 220).

In a second implementation, alone or in combination with the first implementation, forming the high-k gate dielectric layer includes forming a first high-k dielectric layer 246 having a first normalized areal oxygen density (σ/σ_{SiO2}) 1004, and forming a second high-k dielectric layer 248 having a second normalized areal oxygen density 1004 that is greater than the first normalized areal oxygen density 1004.

In a third implementation, alone or in combination with one or more of the first and second implementations, forming the second dummy gate structure comprises forming a low-k gate dielectric layer (e.g., a gate dielectric layer 706) of the dummy gate structure 704, and forming a polysilicon gate electrode (e.g., a gate electrode 708) of the dummy gate structure 704, and replacing the dummy gate structure 704 with the assisting gate structure 212 includes removing the polysilicon gate electrode and a portion of the low-k gate dielectric layer, where a remaining portion of the low-k gate dielectric layer corresponds to a first portion (e.g., a low-k portion 214b) of a gate dielectric layer 214 of the control gate structure 210, and where removing the polysilicon gate electrode and the portion of the low-k gate dielectric layer results in formation of a recess 712, and forming, in the recess a second portion (e.g., a high-k portion 214a) of the gate dielectric layer 214, and a metal gate electrode 216 on the first portion and on the second portion of the gate dielectric layer 214.

In a fourth implementation, alone or in combination with one or more of the first through third implementations, process 1100 includes removing a high-k dielectric layer 248 from the recess prior to forming the metal gate electrode 216.

In a fifth implementation, alone or in combination with one or more of the first through fourth implementations, the first portion of the gate dielectric layer 214 is adjacent to the source/drain region 224, and the second portion of the gate dielectric layer 214 is adjacent to the assisting gate structure 212.

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

In this way, a fin-based TFET includes a control gate structure and an assisting gate structure adjacent to the control gate structure. The assisting gate structure is disposed between the control gate structure and a source/drain region of the fin-based TFET. When a voltage is applied to the assisting gate structure, the assisting gate structure causes the valence band of the fin-based TFET to be raised near the junction between the source/drain region and a channel region in a semiconductor layer under the assisting gate structure. This reduces the tunneling distance between the source/drain region and the channel region, which allows for a lesser threshold voltage to be used for the control gate structure than without the assisting gate structure. In this way, the assisting gate structure may increase switching speed and power efficiency of the fin-based TFET (e.g., because of the lesser threshold voltage.

As described in greater detail above, some implementations described herein provide a semiconductor device. The semiconductor device includes a fin structure extending above a substrate. The semiconductor device includes a first gate structure wrapping around the fin structure on at least three sides of the fin structure. The semiconductor device includes a second gate structure wrapping around the fin structure on the at least three sides of the fin structure, where a first side of the second gate structure is adjacent to a first side of the first gate structure, and where a first gate length of the first gate structure is less than a second gate length of the second gate structure. The semiconductor device includes a first source/drain region on the fin structure, where the first source/drain region is adjacent to a second side of the first gate structure opposing the first side of the first gate structure, and where the first source/drain region includes a first dopant type. The semiconductor device includes a second source/drain region on the fin structure, where the second source/drain region is adjacent to a second side of the second gate structure opposing the first side of the second gate structure, and where the second source/drain region includes a second dopant type different from the first dopant type.

As described in greater detail above, some implementations described herein provide a semiconductor device. The semiconductor device includes a fin structure extending above a substrate. The semiconductor device includes a first gate structure wrapping around the fin structure on at least three sides of the fin structure, where the first gate structure comprises a first gate electrode, and where the first gate electrode comprises a first material having a first work function. The semiconductor device includes a second gate structure wrapping around the fin structure on the at least three sides of the fin structure, where a first side of the second gate structure is adjacent to a first side of the first gate structure, where the second gate structure comprises a second gate electrode, and where the second gate electrode comprises a second material having a second work function that is different from the first work function. The semiconductor device includes a first source/drain region on the fin structure, where the first source/drain region is adjacent to a second side of the first gate structure opposing the first side of the first gate structure, and where the first source/drain region includes a first dopant type. The semiconductor device includes a second source/drain region on the fin structure, where the second source/drain region is adjacent to a second side of the second gate structure opposing the first side of the second gate structure, and where the second source/drain region includes a second dopant type different from the first dopant type.

As described in greater detail above, some implementations described herein provide a method. The method includes forming a fin structure that extends above a substrate of a semiconductor device, where the fin structure comprises an intrinsic semiconductor material. The method includes forming a first dummy gate structure on the fin structure such that the first dummy gate structure wraps around at least three sides of the fin structure. The method includes forming a second dummy gate structure on the fin structure such that the first dummy gate structure wraps around the at least three sides of the fin structure, where a first side of the first dummy gate structure is adjacent to a first side of the second dummy gate structure. The method includes forming a first source/drain region on the fin structure such that the first source/drain region is adjacent to a second side of the first dummy gate structure opposing the first side of the first dummy gate structure, where the first source/drain region comprises a first doped semiconductor material having a first dopant type. The method includes forming a second source/drain region on the fin structure such that the second source/drain region is adjacent to a second side of the second dummy gate structure opposing the first side of the second dummy gate structure, where the second source/drain region comprises a second doped semiconductor material having a second dopant type different from the first dopant type. The method includes replacing, after forming the first source/drain region and the second source/drain region, the first dummy gate structure with an assisting gate structure of a fin-based TFET structure of the semiconductor device. The method includes replacing, after forming the first source/drain region and the second source/drain region, the second dummy gate structure with a control gate structure of the fin-based TFET structure.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a fin structure extending above a substrate,
a first gate structure wrapping around the fin structure on at least three sides of the fin structure;
a second gate structure wrapping around the fin structure on the at least three sides of the fin structure,
wherein a first side of the second gate structure is adjacent to a first side of the first gate structure, and
wherein a first gate length of the first gate structure is less than a second gate length of the second gate structure;
a first source/drain region on the fin structure,
wherein the first source/drain region is adjacent to a second side of the first gate structure opposing the first side of the first gate structure, and
wherein the first source/drain region includes a first dopant type; and
a second source/drain region on the fin structure,
wherein the second source/drain region is adjacent to a second side of the second gate structure opposing the first side of the second gate structure, and
wherein the second source/drain region includes a second dopant type different from the first dopant type.

2. The semiconductor device of claim 1, wherein the fin structure extends in a first direction in the semiconductor device;
wherein the first gate structure and the second gate structure each extend in a second direction in the semiconductor device that is approximately perpendicular to the first direction; and
wherein the first gate length and the second gate length are in the first direction.

3. The semiconductor device of claim 1, wherein a distance between the first gate structure and the second gate structure, at a bottom of the fin structure, is greater than approximately 0 nanometers and less than or equal to approximately 6 nanometers.

4. The semiconductor device of claim 1, wherein the first gate structure comprises:
a flared section; and
a straight section above the flared section.

5. The semiconductor device of claim 4, wherein the second gate structure comprises:
another flared section; and
another straight section above the other flared section.

6. The semiconductor device of claim 4, further comprising:
a first gate dielectric layer between the first gate structure and the fin structure; and
a second gate dielectric layer between the second gate structure and the fin structure,
wherein a thickness of the second gate dielectric layer is greater than a thickness of the first gate dielectric layer.

7. The semiconductor device of claim 1, wherein a first width of a first portion of the fin structure under the first gate structure is greater than a second width of a second portion of the fin structure under the second gate structure.

8. A semiconductor device, comprising:
a fin structure extending above a substrate,
a first gate structure wrapping around the fin structure on at least three sides of the fin structure,
wherein the first gate structure comprises a first gate electrode, and
wherein the first gate electrode comprises a first material having a first work function;
a second gate structure wrapping around the fin structure on the at least three sides of the fin structure,
wherein a first side of the second gate structure is adjacent to a first side of the first gate structure,
wherein the second gate structure comprises a second gate electrode, and
wherein the second gate electrode comprises a second material having a second work function that is different from the first work function;
a first source/drain region on the fin structure,
wherein the first source/drain region is adjacent to a second side of the first gate structure opposing the first side of the first gate structure, and
wherein the first source/drain region includes a first dopant type; and
a second source/drain region on the fin structure,
wherein the second source/drain region is adjacent to a second side of the second gate structure opposing the first side of the second gate structure, and
wherein the second source/drain region includes a second dopant type different from the first dopant type.

9. The semiconductor device of claim 8, wherein a second gate length of the second gate structure is greater than a first gate length of the first gate structure.

10. The semiconductor device of claim 8, wherein the first gate structure comprises:
a flared section; and
a straight section above the flared section.

11. The semiconductor device of claim 10, wherein a transition between the flared section and the straight section is located approximately at a top of the first source/drain region and the second source/drain region.

12. The semiconductor device of claim 8, wherein the second gate structure comprises a gate dielectric layer between the second gate electrode and the fin structure; and
wherein the gate dielectric layer comprises:
a first portion adjacent to the first gate structure; and
a second portion adjacent to the second source/drain region,
wherein the first portion and the second portion comprise different materials.

13. The semiconductor device of claim 8, wherein the first gate structure comprises a gate dielectric layer stack between the first gate electrode and the fin structure; and
wherein the gate dielectric layer stack comprises:
a low dielectric constant (low-k) dielectric layer between the first gate electrode and the fin structure; and
a plurality of high dielectric constant (high-k) dielectric layers between the low-k dielectric layer and the first gate electrode.

14. The semiconductor device of claim 8, wherein the second gate structure includes a greater quantity of gate electrode layers than the first gate structure.

15. A method, comprising:
forming a fin structure that extends above a substrate of a semiconductor device (200),
wherein the fin structure comprises an intrinsic semiconductor material;
forming a first dummy gate structure on the fin structure such that the first dummy gate structure wraps around at least three sides of the fin structure;
forming a second dummy gate structure on the fin structure such that the second dummy gate structure wraps around the at least three sides of the fin structure,
wherein a first side of the first dummy gate structure is adjacent to a first side of the second dummy gate structure;
forming a first source/drain region on the fin structure such that the first source/drain region is adjacent to a second side of the first dummy gate structure opposing the first side of the first dummy gate structure,
wherein the first source/drain region comprises a first doped semiconductor material having a first dopant type;
forming a second source/drain region on the fin structure such that the second source/drain region is adjacent to a second side of the second dummy gate structure opposing the first side of the second dummy gate structure,
wherein the second source/drain region comprises a second doped semiconductor material having a second dopant type different from the first dopant type;
replacing, after forming the first source/drain region and the second source/drain region, the first dummy gate structure with an assisting gate structure of a fin-based tunneling field effect transistor (TFET) structure of the semiconductor device; and
replacing, after forming the first source/drain region and the second source/drain region, the second dummy gate structure with a control gate structure of the fin-based TFET structure.

16. The method of claim 15, wherein forming the first dummy gate structure comprises:
forming a low dielectric constant (low-k) gate dielectric layer of the first dummy gate structure; and
forming a polysilicon gate electrode of the first dummy gate structure; and
wherein replacing the first dummy gate structure with the assisting gate structure comprises:
removing the low-k gate dielectric layer and the polysilicon gate electrode,
wherein removing the low-k gate dielectric layer and the polysilicon gate
electrode results in formation of a recess; and
forming, in the recess:
a high dielectric constant (high-k) gate dielectric layer, and
a metal gate electrode.

17. The method of claim 16, wherein forming the high-k gate dielectric layer comprises:
forming a first high-k dielectric layer having a first normalized areal oxygen density (σ/σ_{SiO2}); and
forming a second high-k dielectric layer having a second normalized areal oxygen density that is greater than the first normalized areal oxygen density.

18. The method of claim 15, wherein forming the second dummy gate structure comprises:
forming a low dielectric constant (low-k) gate dielectric layer of the first dummy gate structure; and
forming a polysilicon gate electrode of the first dummy gate structure; and
wherein replacing the first dummy gate structure with the assisting gate structure comprises:
removing the polysilicon gate electrode and a portion of the low-k gate dielectric layer,
wherein a remaining portion of the low-k gate dielectric layer corresponds to a first portion of a gate dielectric layer of the control gate structure; and
wherein removing the polysilicon gate electrode and the portion of the low-k gate dielectric layer results in formation of a recess; and
forming, in the recess:
a second portion of the gate dielectric layer, and
a metal gate electrode on the first portion and the second portion of the gate dielectric layer.

19. The method of claim 18, further comprising:
removing a high dielectric constant (high-k) layer from the recess prior to forming the metal gate electrode.

20. The method of claim 18, wherein the first portion of the gate dielectric layer is adjacent to the second source/drain region; and
wherein the second portion of the gate dielectric layer is adjacent to the assisting gate structure.
